(19) United States
(12) Patent Application Publication
(10) Pub. No.: US 2023/0268200 A1
(43) Pub. Date: Aug. 24, 2023

(54) FLUID DELIVERY MODULE

(71) Applicant: Ichor Systems, Inc., Fremont, CA (US)

(72) Inventor: Stephen Carson, Woodstock, NY (US)

(21) Appl. No.: 18/097,548

(22) Filed: Jan. 17, 2023

Related U.S. Application Data
(60) Provisional application No. 63/312,989, filed on Feb. 23, 2022.
(60) Provisional application No. 63/410,666, filed on Sep. 28, 2022.

(51) Int. Cl. H01L 21/67

(52) U.S. Cl. CPC H01L 21/67017; H01L 21/67248; H01L 21/67253

(57) ABSTRACT

Apparatuses for controlling fluid flow are important components for delivering process fluids for semiconductor fabrication. These apparatuses for controlling fluid flow are formed with a variety of fluid flow components, including fluid flow components for measuring various properties of process fluids. Fluid flow components for measuring may be constructed to monitor properties such as temperature and pressure, and may do so via sensing elements which also serve to enclose a portion of a flow path within the fluid flow component.

### CROSS-REFERENCE TO RELATED APPLICATIONS

This application claims the benefit of U.S. Provisional Application 63/312,989, filed Feb. 23, 2022, and U.S. Provisional Application 63/410,666, filed Sep. 28, 2022, which are incorporated herein by reference in their entireties.

### BACKGROUND

Flow control has been one of the key technologies in semiconductor chip fabrication. Apparatuses for controlling fluid flow are important for delivering flows of process fluids for semiconductor fabrication and other industrial processes. Such devices are used to measure and accurately control the flow of fluids for a variety of applications. This control relies on apparatuses which are designed for increased packaging density and improved functional performance.

As the technology of chip fabrication has improved, the component size has decreased and packaging requirements have become tighter for the apparatuses for controlling flow. Improvement of functional performance and decreased space requirements have driven improvements in all manner of flow control devices. In order to improve the functional performance of flow control devices improved methods and equipment are desired.

### BRIEF SUMMARY

The present technology is directed to a fluid delivery module comprising an apparatus for controlling flow. The apparatus for controlling flow includes a flow component which measures one or more properties of a process fluid. Apparatuses for controlling flow may incorporate a wide number of fluid flow components to perform a wide range of control functions beyond mere measurement. Where measurement is required, it is desirable to achieve accurate measurement, fast response time, and have minimal impact on fluid flow. Such apparatuses may be used in a wide range of processes such as semiconductor chip fabrication, solar panel fabrication, and the like.

In one implementation, the invention is a system for processing articles. The system has a fluid supply configured to supply a process fluid, a process chamber configured to process articles, and a fluid delivery module. The fluid delivery module has an inlet fluidly coupled to the fluid supply, an outlet fluidly coupled to the process chamber, a flow passage extending from the inlet to the outlet, and a fluid flow component. The fluid flow component has a component base, an inlet port formed in the component base, an outlet port formed in the component base, and a flow path. The flow path extends from the inlet port to the outlet port, the flow path forming a portion of the flow passage. The fluid flow component further has a sensing port in fluid communication with the flow path and located between the inlet port and the outlet port. The fluid flow component has a sensing element sealing the sensing port and a sensor isolated from the process fluid by the sensing element. The sensor is configured to detect a property of the process fluid within the flow path.

In one implementation, the invention is a system for processing articles. The system has a fluid supply configured to supply at least one process fluid, a process chamber configured to process articles, and a fluid delivery module. The fluid delivery module has an inlet fluidly coupled to the fluid supply, an outlet fluidly coupled to the process chamber, a flow passage extending from the inlet to the outlet, a first fluid flow component, and a second fluid flow component. The first fluid flow component has a first component base, a first inlet port formed in the first component base, a first outlet port formed in the first component base, and a first flow path. The first flow path extends from the first inlet port to the first outlet port, the first flow path forming a portion of the flow passage. The first fluid flow component further has a first sensor configured to detect a first property of the at least one process fluid within the first flow path. A first sensor housing is coupled to the first component base, the first sensor housing enclosing the first sensor. The second fluid flow component has a second component base, a second inlet port formed in the second component base, a second outlet port formed in the second component base, and a second flow path. The second flow path extends from the second inlet port to the second outlet port, the second flow path forming a portion of the flow passage. The second fluid flow component further has a second sensor configured to detect a second property of the at least one process fluid within the second flow path. A second sensor housing is coupled to the second component base, the second sensor housing enclosing the second sensor. The first and second sensors are different. The first and second sensor housings are identical.

In another implementation, the invention is a fluid flow component. The fluid flow component has a component base, an inlet port formed in the component base, an outlet port formed in the component base, and a flow path. The flow path extends from the inlet port to the outlet port. The fluid flow component further has a sensing port in fluid communication with the flow path and located between the inlet port and the outlet port. The fluid flow component has a sensing element sealing the sensing port and a sensor isolated from the process fluid by the sensing element. The sensor is configured to detect a property of the process fluid within the flow path.

In another implementation, the invention is a method of manufacturing articles. First, a fluid delivery module is provided. The delivery module has an inlet, an outlet, a flow passage extending from the inlet to the outlet, and a fluid flow component having a flow path extending from an inlet port to an outlet port, the flow path forming a portion of the flow passage. Second, a process fluid is supplied to the inlet of the fluid delivery module. Third, the process fluid is flowed through the flow passage, the process fluid flowing through the flow path of the fluid flow component to the outlet of the fluid delivery module. The outlet of the fluid delivery module is fluidly coupled to an outlet manifold. Fourth, a property of the process fluid is measured via a sensing port in fluid communication with the flow path of the fluid flow component between the inlet port and the outlet port. The sensing port is sealed by a sensing element. A sensor is operably coupled to the sensing element. Fifth, the process fluid from the outlet of the fluid delivery module is delivered to a processing chamber via the outlet manifold. The outlet manifold is fluidly coupled to the processing chamber. Sixth, a process is performed on an article within the processing chamber.

In yet another implementation, the invention is a fluid flow component having a component base, an inlet port formed in the component base, an outlet port formed in the component base, and a flow path extending from the inlet port to the outlet port. The fluid flow component also has a sensing element, the sensing element having a bottom side and a top side. The bottom side is in contact with a process fluid flowing through the flow path. The flow path has a restriction height and a restriction width at a restriction plane intersecting the sensing element. A restriction ratio between the restriction height and the restriction width is 0.25 or less.

In another implementation, the invention is a fluid flow component having a component base, an inlet port formed in the component base, an outlet port formed in the component base, and a flow path extending from the inlet port to the outlet port. The fluid flow component also has a sensing element, the sensing element having a bottom side and a top side. The bottom side is in contact with a process fluid flowing through the flow path. The flow path has a restriction height at a restriction plane intersecting the sensing element and an unrestricted height extending from the sensing element to a floor of a sensing port. A transition ratio between the restriction height and the unrestricted height is 0.316 or less.

In yet another implementation, the invention is a fluid flow component having a component base, an inlet port formed in the component base, an outlet port formed in the component base, and a flow path extending from the inlet port to the outlet port. The fluid flow component also has a sensing element, the sensing element having a bottom side and a top side. The bottom side is in contact with a process fluid flowing through the flow path. The fluid flow component also has a restriction element configured to obstruct the flow path, the flow path having a restriction height between the restriction element and the bottom side of the sensing element which is less than an unrestricted height measured from the bottom side of the sensing element to a floor of the flow path.

Further areas of applicability of the present technology will become apparent from the detailed description provided hereinafter. It should be understood that the detailed description and specific examples, while indicating the preferred implementation, are intended for purposes of illustration only and are not intended to limit the scope of the technology.

### BRIEF DESCRIPTION OF THE DRAWINGS

The invention of the present disclosure will become more fully understood from the detailed description and the accompanying drawings, wherein:

FIG. 1 is a schematic of a system for manufacturing semiconductor devices utilizing one or more apparatuses for controlling flow.

FIG. 2 is a perspective view of a fluid delivery module comprising a plurality of apparatuses for controlling flow as may be utilized in the process of FIG. 1.

FIG. 3 is a perspective view of a flow component as may be utilized in the fluid delivery module of FIG. 2.

FIG. 4 is an exploded perspective view of the flow component of FIG. 3.

FIG. 5 is a cross-sectional view of the flow component of FIG. 3, taken along line 5-5.

FIG. 6 is a detail view of the area 6 as shown in FIG. 5.

FIG. 7 is a perspective view of a retainer element of the flow component of FIG. 3.

FIG. 8 is a rear bottom perspective view of the retainer element of the flow component of FIG. 3.

FIG. 9 is a perspective view of a sensor housing of the flow component of FIG. 3.

FIG. 10 is a rear bottom perspective view of the sensor housing of the flow component of FIG. 3.

FIG. 11 is a perspective view of a sensor of the flow component of FIG. 3.

FIG. 12 is a rear bottom perspective view of the sensor of the flow component of FIG. 3.

FIG. 13 is a perspective view of a spacer of the flow component of FIG. 3.

FIG. 14 is a rear bottom perspective view of the spacer of the flow component of FIG. 3.

FIG. 15 is a perspective view of an outer base of the flow component of FIG. 3.

FIG. 16 is a rear bottom perspective view of the outer base of the flow component of FIG. 3.

FIG. 17 is a perspective view of a sensing element and an insert of the flow component of FIG. 3.

FIG. 18 is a rear bottom perspective view of the sensing element and the insert of the flow component of FIG. 3.

FIG. 19 is a perspective view of first and second support portions of the flow component of FIG. 3.

FIG. 20 is a rear bottom perspective view of the first and second support portions of the flow component of FIG. 3.

FIG. 21 is a perspective view of a second embodiment of a flow component as may be used in the fluid delivery module of FIG. 2.

FIG. 22 is an exploded perspective view of the flow component of FIG. 21.

FIG. 23 is a cross-sectional view of the flow component of FIG. 21, taken along line 23-23.

FIG. 24 is a perspective view of a sensor of the flow component of FIG. 21.

FIG. 25 is a rear bottom perspective view of the sensor of the flow component of FIG. 21.

FIG. 26 is a perspective view of a third embodiment of a flow component as may be used in the fluid delivery module of FIG. 2.

FIG. 27 is an exploded perspective view of the flow component of FIG. 26.

FIG. 28 is a cross-sectional view of the flow component of FIG. 26, taken along line 28-28.

FIG. 29 is a detail view of the area 29 as shown in FIG. 28.

FIG. 30 is a perspective view of a sensor of the flow component of FIG. 26.

FIG. 31 is a rear bottom perspective view of the sensor of the flow component of FIG. 26.

FIG. 32 is a perspective view of a sensing element and an insert of the flow component of FIG. 26.

FIG. 33 is a rear bottom perspective view of the sensing element and the insert of the flow component of FIG. 26.

FIG. 34 is a perspective view of a fourth embodiment of a flow component as may be used in the fluid delivery module of FIG. 2.

FIG. 35 is an exploded perspective view of the flow component of FIG. 34.

FIG. 36 is a cross-sectional view of the flow component of FIG. 34, taken along line 36-36.

FIG. 37 is a perspective view of a sensor of the flow component of FIG. 34.

FIG. 38 is a rear bottom perspective view of the sensor of the flow component of FIG. 34.

FIG. 39 is a perspective view of a spacer of the flow component of FIG. 34.

FIG. 40 is a rear bottom perspective view of the spacer of the flow component of FIG. 34.

FIG. 41 is a perspective view of a seal of the flow component of FIG. 34.

FIG. 42 is a rear bottom perspective view of the seal of the flow component of FIG. 34.

FIG. 43 is a perspective view of a fifth embodiment of a flow component as may be used in the fluid delivery module of FIG. 2.

FIG. 44 is an exploded perspective view of the flow component of FIG. 43.

FIG. 45 is a cross-sectional view of the flow component of FIG. 43, taken along line 45-45.

FIG. 46 is a perspective view of a sixth embodiment of a flow component as may be used in the fluid delivery module of FIG. 2.

FIG. 47 is an exploded perspective view of the flow component of FIG. 46.

FIG. 48 is a perspective view of a portion of a seventh embodiment of a flow component as may be used in the fluid delivery module of FIG. 2.

FIG. 49 is an exploded perspective view of the portion of the flow component of FIG. 48.

FIG. 50 is a cross-sectional view of the portion of the flow component of FIG. 48, taken along line 50-50.

FIG. 51 is a perspective view of a portion of an eighth embodiment of a flow component as may be used in the fluid delivery module of FIG. 2.

FIG. 52 is a cross-sectional view of the portion of the flow component of FIG. 51, taken along line 52-52.

FIG. 53 is a perspective view of a portion of a ninth embodiment of a flow component as may be used in the fluid delivery module of FIG. 2.

FIG. 54 is a cross-sectional view of the portion of the flow component of FIG. 53, taken along line 54-54.

FIG. 55 is a perspective view of a portion of a tenth embodiment of a flow component as may be used in the fluid delivery module of FIG. 2.

FIG. 56 is a cross-sectional view of the portion of the flow component of FIG. 55, taken along line 56-56.

FIG. 57 is a perspective view of a portion of an eleventh embodiment of a flow component as may be used in the fluid delivery module of FIG. 2.

FIG. 58 is a cross-sectional view of the portion of the flow component of FIG. 57, taken along line 58-58.

FIG. 59 is a perspective view of a portion of a twelfth embodiment of a flow component as may be used in the fluid delivery module of FIG. 2.

FIG. 60 is a cross-sectional view of the portion of the flow component of FIG. 59, taken along line 60-60.

FIG. 61 is a perspective view of a portion of a thirteenth embodiment of a flow component as may be used in the fluid delivery module of FIG. 2.

FIG. 62 is a cross-sectional view of the portion of the flow component of FIG. 61 in a neutral state, taken along line 62-62.

FIG. 63 is a cross-sectional view of the portion of the flow component of FIG. 61 in a retracted state, taken along line 62-62.

FIG. 64 is a cross-sectional view of the portion of the flow component of FIG. 61 in a extended state, taken along line 62-62.

FIGS. 65-72 are graphs of temperature at the sensing element versus time for various restriction heights in the flow path and various fluid flow rates.

FIGS. 73-80 are graphs of temperature at the sensing element versus time for various sensing element thicknesses and various fluid flow rates.

All drawings are schematic and not necessarily to scale. Features shown numbered in certain figures which may appear un-numbered in other figures are the same features unless noted otherwise herein.

### DETAILED DESCRIPTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

The present invention is directed to a fluid flow component for use in a fluid delivery module and system. Semiconductor fabrication is one industry which demands high performance in control of fluid flows. As semiconductor fabrication techniques have advanced, customers have recognized the need for flow control devices with improved functional performance. Thus, fluid flow components used for sensing properties of process fluids must achieve faster response times, increased accuracy, and be packaged in increasingly dense assemblies. The present invention enables superior sensing in semiconductor and similar processes.

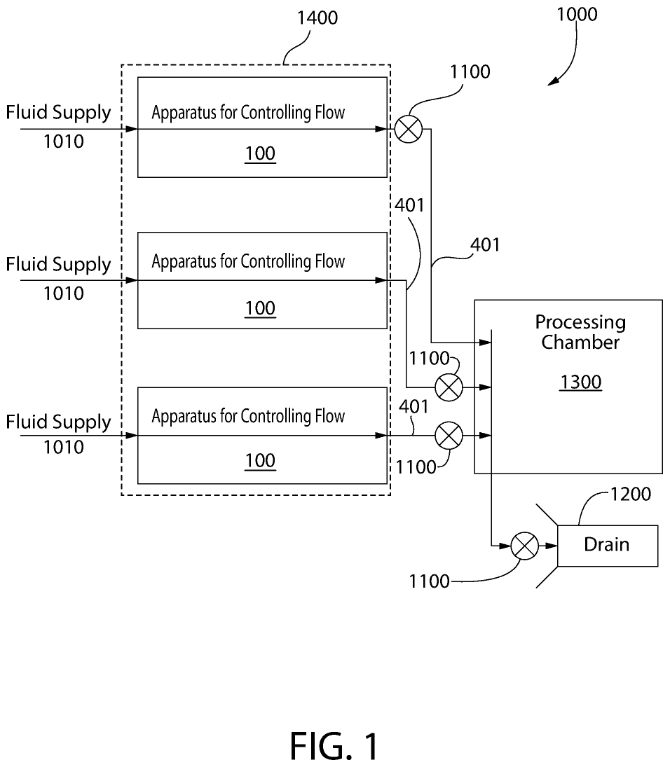

FIG. 1 shows a schematic of an exemplary processing system 1000. The processing system 1000 may utilize a plurality of apparatus for controlling flow 100 fluidly coupled to a processing chamber 1300. The plurality of apparatus for controlling flow 100 are used to supply one or more different process fluids to the processing chamber 1300. Fluids are provided by a plurality of fluid supplies 1010. As can be seen, two or more fluid supplies 1010 can be connected to a single apparatus for controlling flow 100. Collectively, the plurality of apparatus for controlling flow 100 belong to a fluid delivery module 1400. Optionally, more than one fluid delivery module 1400 may be utilized in the processing system 100. The plurality of apparatus for controlling flow 100 are connected to the processing chamber 1300 by an outlet manifold 401. Articles such as semiconductors and integrated circuits may be processed within the processing chamber 1300.

Valves 1100 isolate each of the apparatus for controlling flow 100 from the processing chamber 1300, enabling each of the apparatus for controlling flow 100 to be selectively connected or isolated from the processing chamber 1300, facilitating a wide variety of different processing steps. The processing chamber 1300 may contain an applicator to apply process fluids delivered by the plurality of apparatus for controlling flow 100, enabling selective or diffuse distribution of the fluids supplied by the plurality of apparatus for controlling flow 100. Optionally, the processing chamber 1300 may be a vacuum chamber or may be a tank or bath for immersing articles in the fluids supplied by the plurality of apparatus for controlling flow 100. A fluid supply line is formed by the flow path from each of the respective fluid supplies to the processing chamber 1300.

In addition, the processing system 1000 may further comprise a vacuum source or drain 1200 which is isolated from the processing chamber 1300 by a valve 1100 to enable evacuation of process fluids or facilitate purging one or more of the apparatus for controlling flow 100. This enables maintenance, switching between process fluids in the same apparatus for controlling flow 100, or other tasks. Optionally, the drain 1200 may be a liquid drain configured to remove liquids from the processing chamber 1300. Alternately, the drain 1200 may be a vacuum source for removing gases. Optionally, the apparatus for controlling flow 100 may be mass flow controllers, flow splitters, flow combiners, or any other device which controls the flow of a process fluid in a processing system. Furthermore, the valves 1100 may be integrated into the apparatus for controlling flow 100 if so desired. The processing chamber 1300 may house a semiconductor wafer for processing, among other articles.

Processes that may be performed in the processing system 1000 may include wet cleaning, photolithography, ion implantation, dry etching, atomic layer etching, wet etching, plasma ashing, rapid thermal annealing, furnace annealing, thermal oxidation, chemical vapor deposition, atomic layer deposition, physical vapor deposition, molecular beam epitaxy, laser lift-off, electrochemical deposition, chemical-mechanical polishing, wafer testing, electroplating, or any other process utilizing gases or liquids.

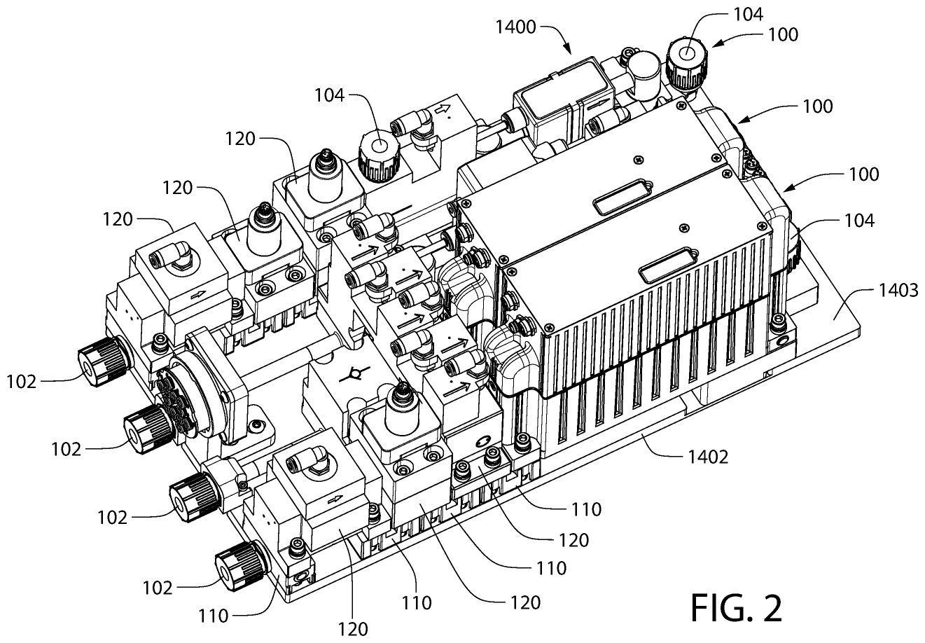

FIG. 2 shows an exemplary fluid delivery module 1400 comprising a plurality of apparatus for controlling flow 100. The fluid delivery module 1400 comprises a support structure 1402. The support structure 1402 may be referred to as a base substrate or base plate and is generally a flat plate or sheet with one or more apparatuses for controlling flow 100 mounted thereon. In the present example, a plurality of apparatus for controlling flow 100 are mounted to the support structure. Each of the apparatus for controlling flow 100 are modular in design, and comprise a large number of individual fluid flow components 110, 120 which are each attached to the support structure 1402 either directly or indirectly. The support structure 1402 has a top surface 1403 onto which the apparatuses for controlling flow 100 are mounted.

Fluid flow components 110, 120 include active flow components 120 and passive flow components 110. Passive flow components 110 do not alter the flow of the fluid, but instead merely connect one active component to another or connect an active component to an inlet or outlet. Active flow components 120 may alter the flow of fluid, monitor an aspect of the fluid, or otherwise perform a function beyond mere fluid conveyance. Active flow components 120 may include temperature sensors, pressure transducers, mass flow controllers, valves, and the like. Yet other components may be both active and passive depending on their current use in an apparatus for controlling flow 100. For instance, a temperature sensor may also serve as a passive fluid flow component which conveys fluid from one active flow component 120 to another and may not actually be utilized to measure temperature sensor. As can be seen, a huge number of variations in fluid flow components 110, 120 can be conceived, and these fluid flow components 110, 120 can be used to assemble a wide range of apparatus for controlling flow 100.

The fluid delivery module 1400 comprises a plurality of inlets 102 which receive fluid from the fluid supplies 1010 discussed above. The fluid delivery module also has at least one outlet 104 which delivers fluid to the processing chamber 1300. Each apparatus for controlling flow 100 may have one inlet 102 and one outlet 104 or may have a plurality of inlets 102 or a plurality of outlets 104. Thus, fluid may flow through a plurality of inlets 102 and be delivered via a single outlet 104 or may flow through a single inlet 102 and be delivered via a plurality of outlets 104. The same fluid may be delivered to a plurality of inlets 102 or different fluids may be delivered to each inlet 102. The same inlet 102 or outlet 104 may be shared by a plurality of apparatus for controlling flow 100 or each apparatus for controlling flow 100 may have one or more dedicated inlets 102 and outlets 104.

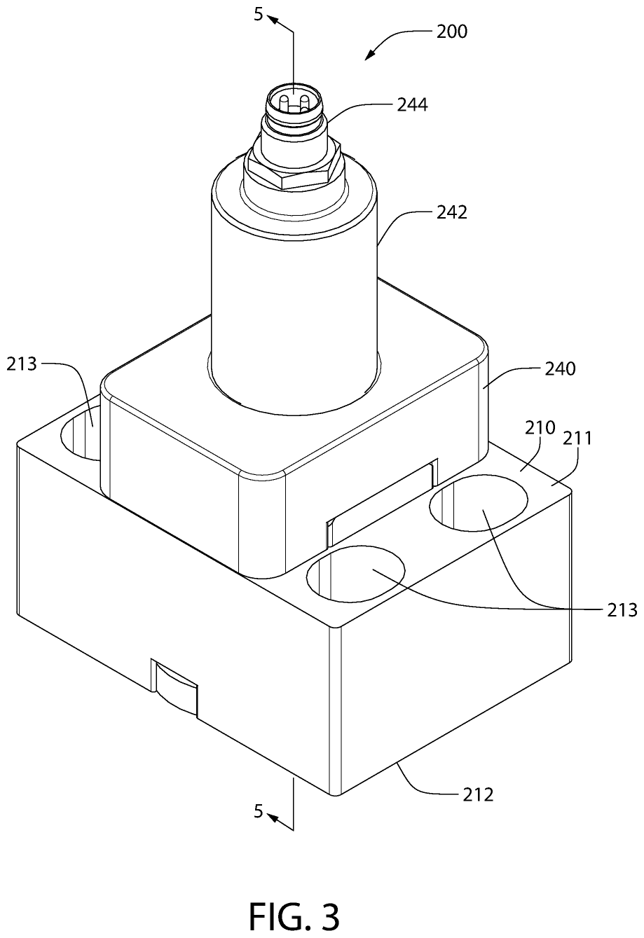

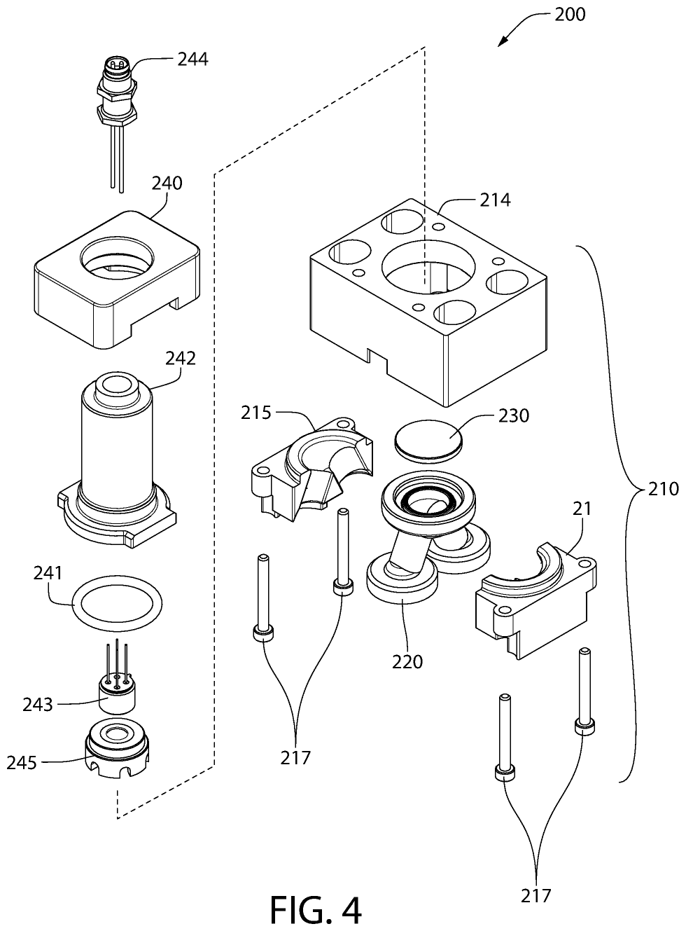

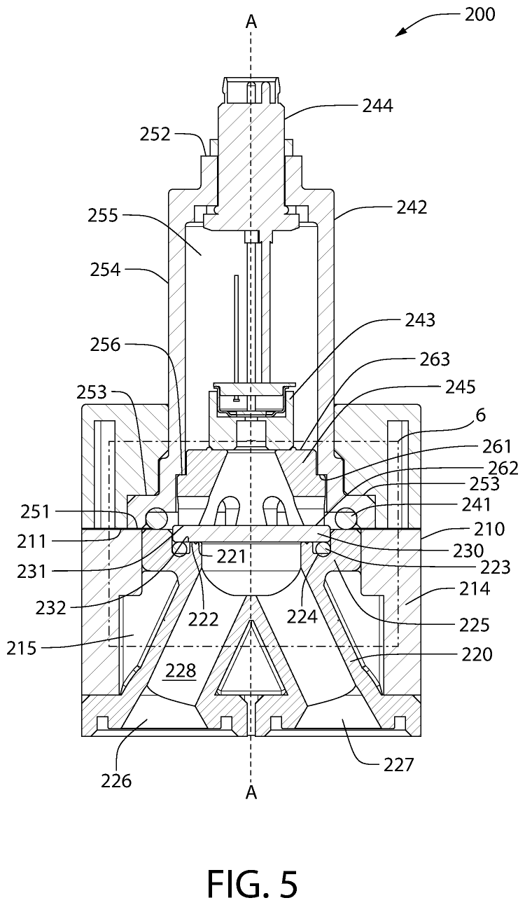

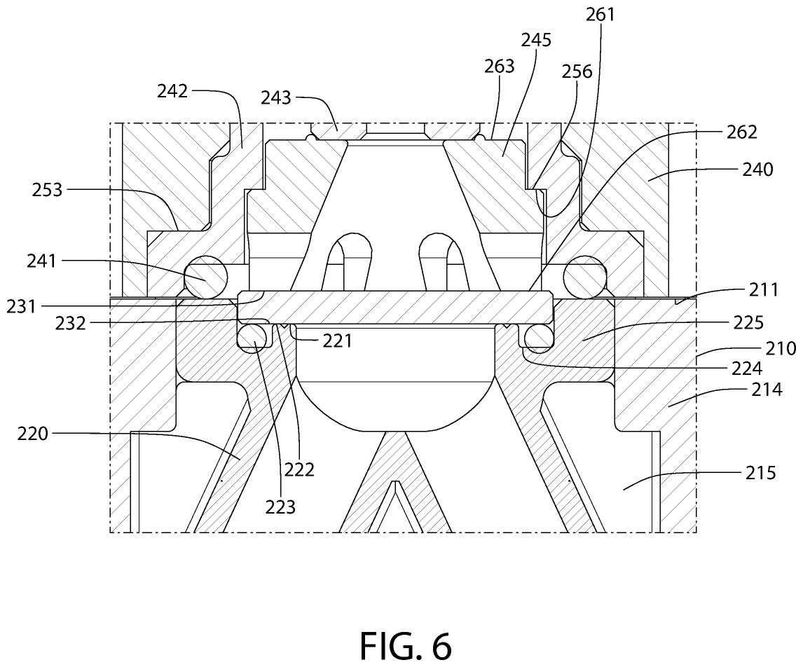

Turning to FIGS. 3-6, a fluid flow component 200 is illustrated. In the present embodiment, the fluid flow component 200 is a temperature sensor configured to measure a temperature of a fluid as it flows through the fluid flow component 200. The fluid flow component 200 is an active component because it actively monitors a property of the fluid. The component 200 has a component base 210, a retainer element 240, a sensor housing 242, and a connector 244. The component base 210 has a top surface 211 and a bottom surface 212. The bottom surface 212 mounts to other fluid flow components 110, 120 as will be discussed in greater detail below. The top surface 211 receives the retainer element 240 and the sensor housing 242 as shown.

The component base 210 further incorporates fastener passageways 213, the fastener passageways 213 extending through the component base 210 to permit securing the fluid flow component 200 to other fluid flow components 110, 120 or to the support structure 1402. The fastener passageways 213 may incorporate counter bores, counter sinks, or other features which permit recessing the fasteners below the top surface 211.

The component base 210 collectively comprises an outer base 214, a first support portion 215, a second support portion 216, an insert 220, and a plurality of fasteners 217. As can be seen, the component base 210 is constructed from a plurality of separate components which enable flow of fluid through the fluid flow component 200. The insert 220 is surrounded by the first and second support portions 215, 216. The first and second support portions 215, 216 nest into the outer base 214 and are secured during assembly by the fasteners 217. This allows the component base 210 to be formed from a plurality of different components to optimize strength, cost, or other factors. For instance, the insert 220 may be formed of a material that is non-reactive to the fluids which will be utilized, while the other components may be formed of a material optimized for cost or other factors. In yet other embodiments, the component base 210 may be formed as a single component which is monolithic and integrally formed.

The fluid flow component 200 further comprises a sensing element 230, a spacer 245, a sensor 243, an O-ring 241, the retainer element 240, the sensor housing 242, and the connector 244. The sensor housing 242 encloses the sensing element 230, spacer 245, sensor 243, and the O-ring 241. The connector 244 is also mounted partially within the sensor housing 242. The retainer element 240 secures the sensor housing 242 to the component base 210.

The connector 244 may be a panel mount connector, or any other type of connector which enables electrical connection with the sensor 243. The connector 244 is electrically connected to the sensor 243, enabling operation of the sensor 243 and allowing measurement of one or more properties of the fluid passing through the fluid flow component 200. The connector 244 may instead be replaced by a length of wire emerging from the sensor housing 242 instead of a panel mount or other electrical connector if so desired.

The sensor housing 242 extends from a base surface 251 to a distal end 252. The connector 244 is located in an aperture in the distal end 252 while the base surface 251 engages the top surface 211 of the component base 210. A flange 253 extends from a housing body 254 and forms a portion of the base surface 251. The flange 253 engages the retainer element 240. When the retainer element 240 is secured to the top surface 211 of the component base 210, the flange 253 is also pressed against the top surface 211 of the component base 210.

The sensor housing 242 further incorporates a cavity 255. The cavity 255 is configured to receive the sensing element 230, spacer 245, and sensor 243 as discussed above. The cavity 255 incorporates a clamping surface 256 which engages a shoulder surface 261 of the spacer 245 as will be discussed in greater detail below. Thus, the clamping surface 256 of the sensor housing 242 is in direct physical contact with the shoulder surface 261 of the spacer 245. The sensor 243 engages a sensor surface 263, the sensor surface 263 incorporating sensor engagement features such as ribs which ensure that the sensor 243 is properly positioned within the sensor housing 242. The sensor 243 is in direct physical contact with the sensor surface 263 of the spacer 245.

The spacer 245 is compressed between the sensor housing 242 and the sensing element 230 by the interaction between the clamping surface 256 of the sensor housing 242 and the shoulder surface 261 of the spacer 245. The sensing element 230 has a top surface 231 and a bottom surface 232. A bottom surface 262 of the spacer 245 engages the top surface 231 of the sensing element 230, while the bottom surface 232 engages a first sealing rib 221, a second sealing rib 222, of the insert 220 and an O-ring 223 located in a groove 224 of the insert 220. Thus, the interface between the insert 220 and the sensing element 230 comprises three seals which prevent fluid leakage. The spacer 245 compresses the sensing element 230 against the first sealing rib 221, the second sealing rib 222, and the O-ring 223. The first sealing rib 221 is concentric with the second sealing rib 222 and the groove 224. The sensing element 230 may be formed of a hard material such as sapphire, or in other embodiments, it may be formed of a polymer such as polytetrafluoroethane (“PTFE”) or another similar material. In the present embodiment, the sensing element 230 is formed as a disk having constant thickness, and may range in thickness from 0.5 mm to 3 mm, depending on design requirements. The top surface 231 of the sensing element 230 is in direct physical contact with the bottom surface 262 of the spacer 245 while the bottom surface 232 of the sensing element 230 is in direct physical contact with the first sealing rib 221 and the second sealing rib 222 of the insert 220.

The insert 220 has a sensing port 225, a first port 226, and a second port 227. The first and second ports 226, 227 may be either inlet or outlet ports for connecting fluid thereto. Thus, fluid may flow in either direction through a flow path 228 extending from the first port 226 to the second port 227. The sensing port 225 is fluidly coupled to the flow path 228 between the first port 226 and the second port 227. A longitudinal axis A-A extends through a center of the sensing port 225 such that the sensing port 225 is rotationally symmetric about the longitudinal axis A-A. The longitudinal axis A-A also extends through a center of the sensor housing 242, spacer 245, sensor 243, and sensing element 230. In the present embodiment, the flow path 228 is symmetrical with respect to the sensing port 225. Otherwise stated, reversing flow through the flow path 228 would not alter the path that fluid takes through the fluid flow component 200. In other embodiments, the flow path 228 need not be symmetrical and may be different between the first port 226 and the sensing port 225 as compared with the second port 227 and the sensing port 225.

The sensing port 225 of the insert 220 comprises the first sealing rib 221, second sealing rib 222, and the groove 224. Thus, the first and second sealing ribs 221, 222 and the groove 224 form a portion of the sensing port 225 and may be altered depending on design requirements. This may include the pressure or material within the flow path 228, and may necessitate different sealing geometry to achieve the desired performance. The interface between the bottom surface 232 of the sensing element 230 and the first sealing rib 221 forms a first seal. The interface between the bottom surface 232 of the sensing element and the second sealing rib 222 forms a second seal. The interface between the bottom surface 232 and the O-ring 223 within the groove 224 forms a third seal. Thus, three distinct seals may be formed to ensure high resistance to leakage. In other embodiments, the O-ring 223 and groove 224 may be omitted. In yet other embodiments, one of the first and second sealing ribs 221, 222 may be omitted.

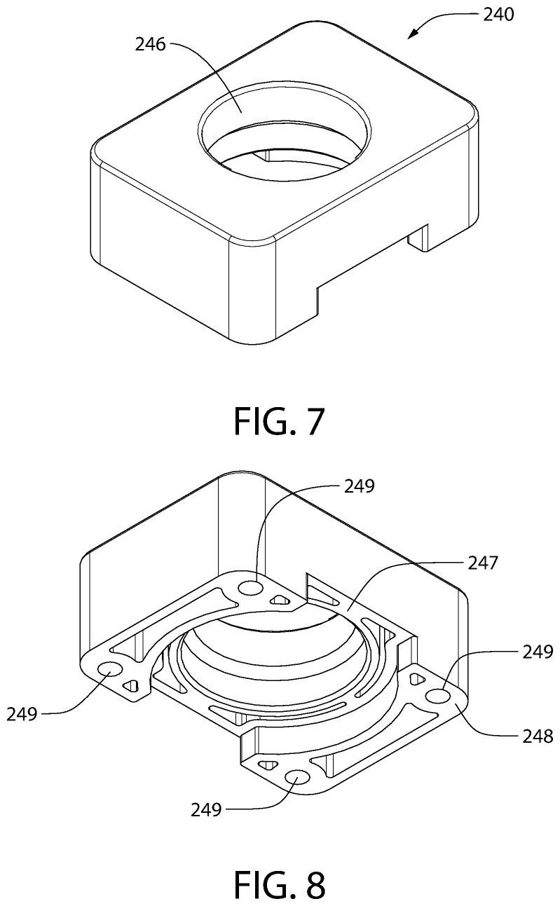

Turning to FIGS. 7 and 8, the retainer element 240 is shown in greater detail. The retainer element 240 has a housing aperture 246 which allows passage of the housing body 254 of the sensor housing 242. A flange engaging surface 247 extends from the housing aperture 246. The flange engaging surface 247 engages the flange 253 of the sensor housing 242, allowing the sensor housing 242 to be compressed against the top surface 211 of the component base 210. The retainer element 240 further comprises a bottom surface 248. During assembly, the bottom surface 248 is substantially coplanar with the base surface 251 of the sensor housing 242. The bottom surface 248 is also in contact with the top surface 211 of the component base 210, but in other embodiments it may be spaced from the top surface 211. A plurality of fastener passageways 249 receive the fasteners 217 to secure the retainer element 240 to the component base 210.

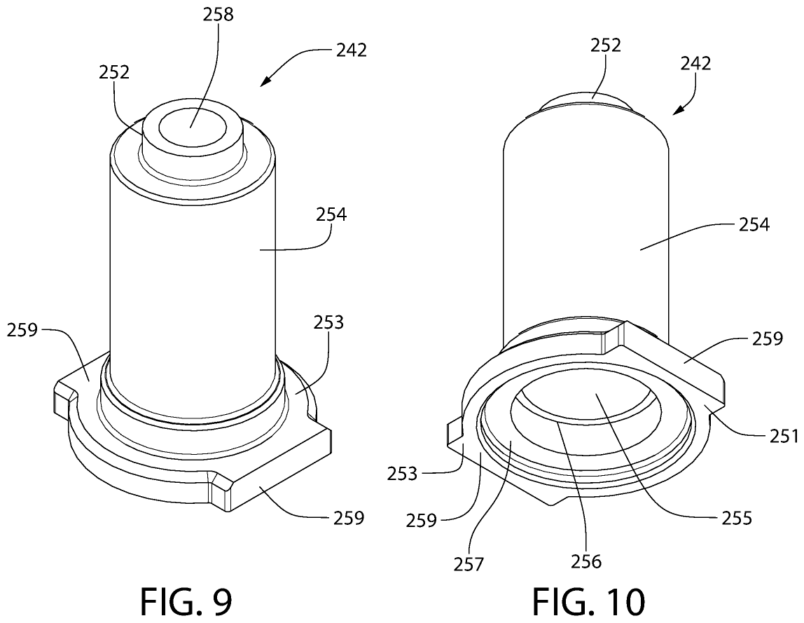

FIGS. 9 and 10 illustrate the sensor housing 242 in greater detail. As discussed above, the sensor housing 242 extends from the base surface 251 to the distal end 252. The flange 253 forms a portion of the base surface 251 and extends from the housing body 254. A seal surface 257 is located within the cavity adjacent the base surface 251, the seal surface 257 engaging the O-ring 241 to seal the cavity 255 from the outside environment. A connector aperture 258 is located at the distal end 252 and configured to receive the connector 244. The cavity 255 further includes the clamping surface 256, the clamping surface 256 being located closer to the distal end 252 than the seal surface 257. The flange 253 comprises a pair of wings 259 extending from opposite sides of the housing body 254 to increase the contact area between the flange 253 and the flange engaging surface 247 of the retainer element 240.

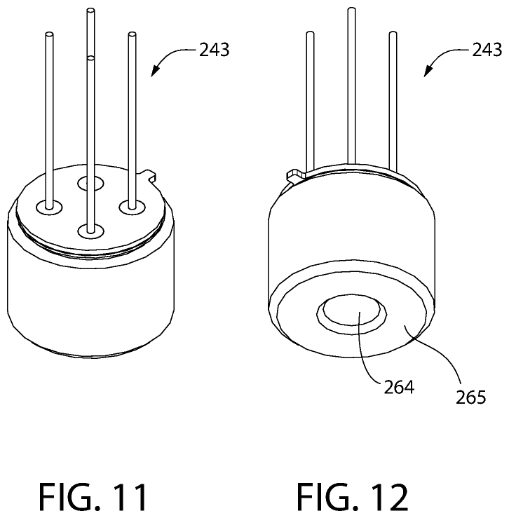

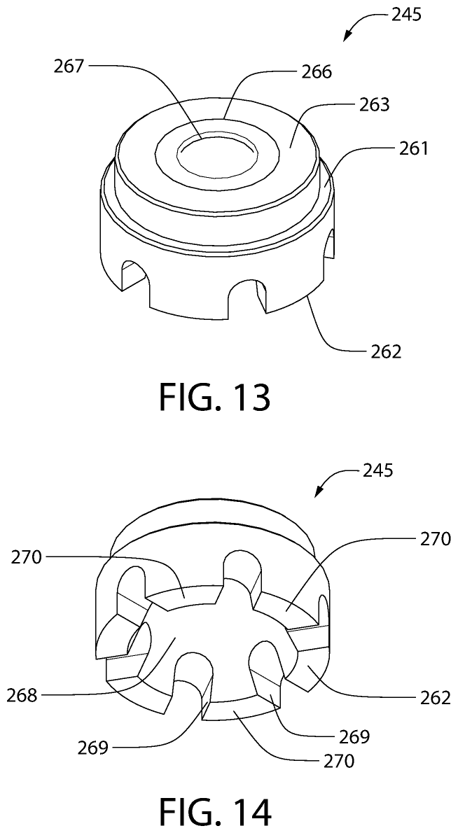

Turning to FIGS. 11-14, the sensor 243 and spacer 245 are illustrated. The sensor 243 has a sensing aperture 264 formed in a sensing surface 265 of the sensor. The sensing aperture 264 allows the sensor 243 to detect the physical property being measured. In the present embodiment, the sensing aperture 264 allows passage of electromagnetic waves which allow detection of temperature of the fluid. In the present embodiment, the sensor 243 detects temperature by measuring infrared electromagnetic waves received at the sensing aperture 264. The sensing surface 265 is in physical contact with the sensor surface 263 of the spacer 245 as discussed above. Thus, the sensor 243 is positioned such that its sensing aperture 264 is located at a fixed location along the longitudinal axis A-A and centered on the longitudinal axis A-A.

The spacer 245 extends from the sensor surface 263 to the bottom surface 262 along the longitudinal axis A-A. The shoulder surface 261 is located between the sensor surface 263 and the bottom surface 262 with respect to the longitudinal axis A-A. The sensor surface 263 incorporates a rib 266 which encircles the sensing surface 265 of the sensor 243, aiding in alignment of the sensing aperture 264 with a spacer aperture 267 formed in the sensor surface 263. The spacer aperture 267 allows passage of electromagnetic waves through the spacer 245 and is centered about the longitudinal axis A-A. The spacer aperture 267 is located at the intersection between the sensor surface 263 and the inner surface 268.

The inner surface 268 extends from the spacer aperture 267 to the bottom surface 262. Preferably, the inner surface 268 is conical in shape, with a diameter that increases with increasing distance from the spacer aperture 267 to the bottom surface 262. The angle of the inner surface 268 with respect to the longitudinal axis A-A is preferably an acute angle as measured between the longitudinal axis A-A and the inner surface 268. Formed into the bottom surface 262 are a plurality of notches 269. The notches 269 are rotationally symmetric about the longitudinal axis A-A and have a width which is less than protuberances 270 forming the bottom surface 262 as measured in a circumferential direction about the longitudinal axis A-A. The protuberances 270 are in direct surface contact with the top surface 231 of the sensing element 230, securing the sensing element 230 to the sensing port 225 of the insert 220.

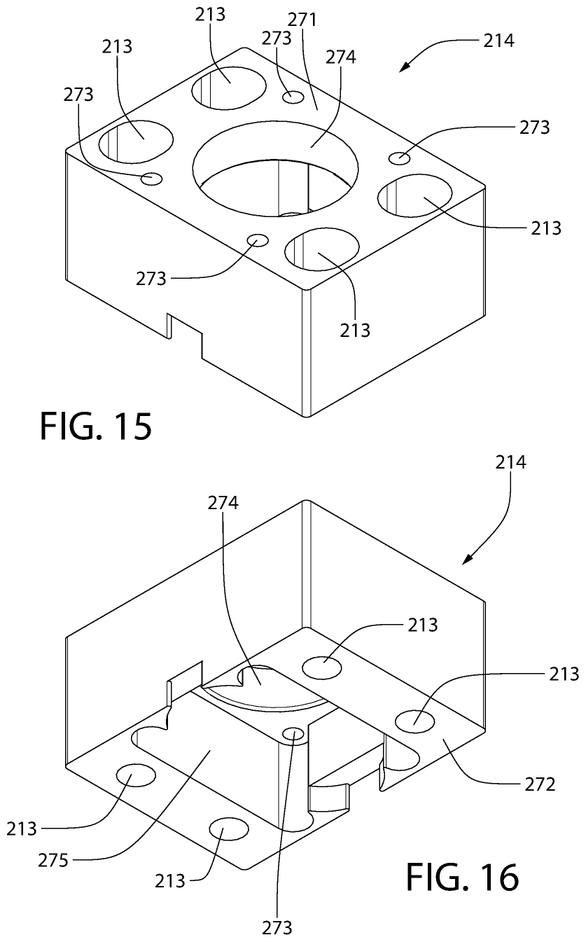

FIGS. 15-20 illustrate the sensing element 230 and the components which collectively form the component base 210. FIGS. 15 and 16 illustrate the outer base 214. As discussed above, the component base 210 has a top surface 211 and a bottom surface 212. The outer base 214 has a top surface 271 and a bottom surface 272. The top surface 271 of the outer base 214 forms a portion of the top surface 211 of the component base 210, while the bottom surface 272 of the outer base 214 forms a portion of the bottom surface 212 of the component base 210. The fastener passageways 213 are formed into the outer base 214 of the component base 210 as discussed previously. Additional fastener passageways 273 are formed into the outer base 214 to allow assembly of the fluid flow component 200.

A port aperture 274 is also formed into the outer base 214 to allow the sensing port 225 of the insert 220 to be accessed through the outer base 214. The port aperture 274 extends from the top surface 271 of the outer base 214 to a component receiving cavity 275. The component receiving cavity 275 is formed unto the bottom surface 272 and is configured to receive the insert 220 and the first and second support portions 215, 216. The fastener passageways 273 extend from the top surface 271 of the outer base 214 to the component receiving cavity 275, while the fastener passageways 213 of the component base 210 extend from the top surface 271 of the outer base 214 to the bottom surface 271 of the outer base 214. The fasteners 217 secure the components of the component base 210 together while also coupling the retainer element 240 to the component base 210. As noted previously, the component base 210 may be formed as a single component, with omission of the insert 220, first support portion 215, and second support portion 216.

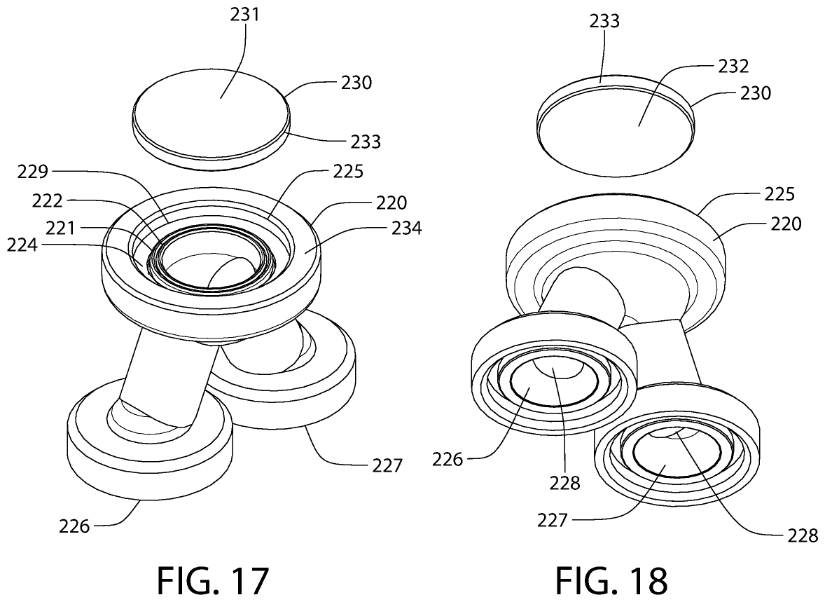

FIGS. 17 and 18 illustrate the insert 220 and the sensing element 230. As discussed above, the sensing element 230 has a top surface 231 and a bottom surface 232. The bottom surface 232 fits within the sensing port 225 of the insert 220. The bottom surface 232 engages the first sealing rib 221, second sealing rib 222, and the O-ring 223 within the groove 224 as previously discussed. The sensing element 230 further comprises an outer diameter 233 which is sized such that the sensing element 230 at least partially nests within an outer wall 229 of the sensing port 225. Thus, the outer diameter 233 of the sensing element 230 is either smaller than the outer wall 229 or has an interference fit therewith, but is not prevented from nesting within the sensing port 225 and engaging the first and second sealing ribs 221, 222.

The insert 220 extends from the first port 226 to the second port 227 along the flow path 228, with the sensing port 225 fluidly coupled to the flow path 228. The sensing port 225 forms a portion of the top surface 211 of the component base 210 while the first and second ports 226, 227 form portions of the bottom surface 212 of the component base 210. An end surface 234 of the sensing port 225 is substantially coplanar with the top surface 271 of the outer base 214. Optionally, the end surface 234 of the sensing port 225 may protrude beyond the top surface 271 of the outer base 214 or it may be recessed with respect to the top surface 271 of the outer base 214.

Similarly, an end surface 235 of each of the first and second ports 226, 227 is substantially coplanar with the bottom surface 272 of the outer base 214. Each of the first and second ports 226, 227 form a portion of the bottom surface 212 of the component base 210. Optionally, the end surfaces 235 of the first and second ports 226, 227 may protrude beyond the bottom surface 272 of the outer base 214 or may be recessed with respect to the bottom surface 272 of the outer base 214.

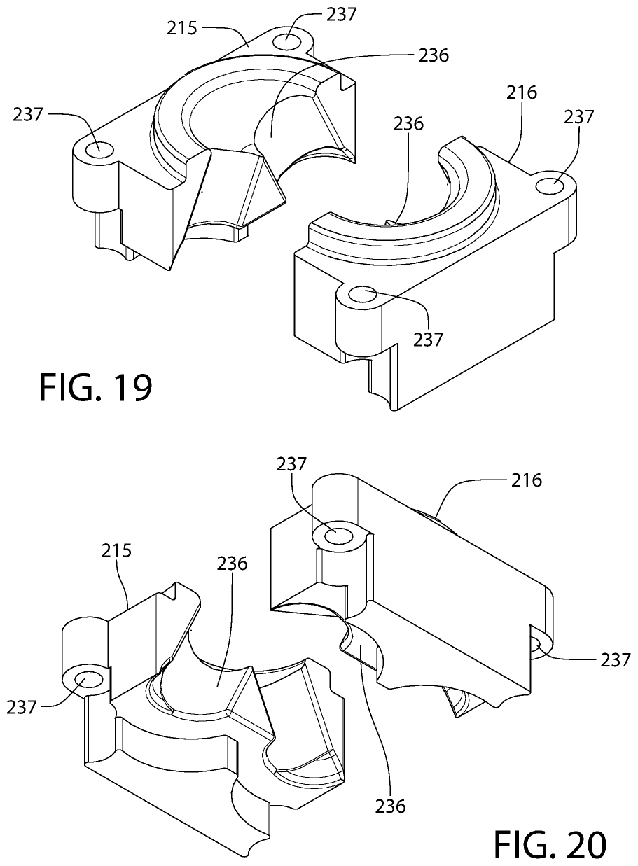

FIGS. 19 and 20 illustrate the first and second support portions 215, 216. The first and second support portions 215, 216 each incorporate an insert receiving section 236 which receives the insert 220. The insert receiving sections 236 provide structural support to the insert 220 and ensure that it is properly positioned within the component base 210. The first and second support portions 215, 216 fit within the component receiving cavity 275 and are secured within the component receiving cavity 275 via the fasteners 217. The fasteners 217 extend through fastener passageways 237 to provide secure retention of the first and second support portions 215, 216 and the insert 220 within the outer base 214.

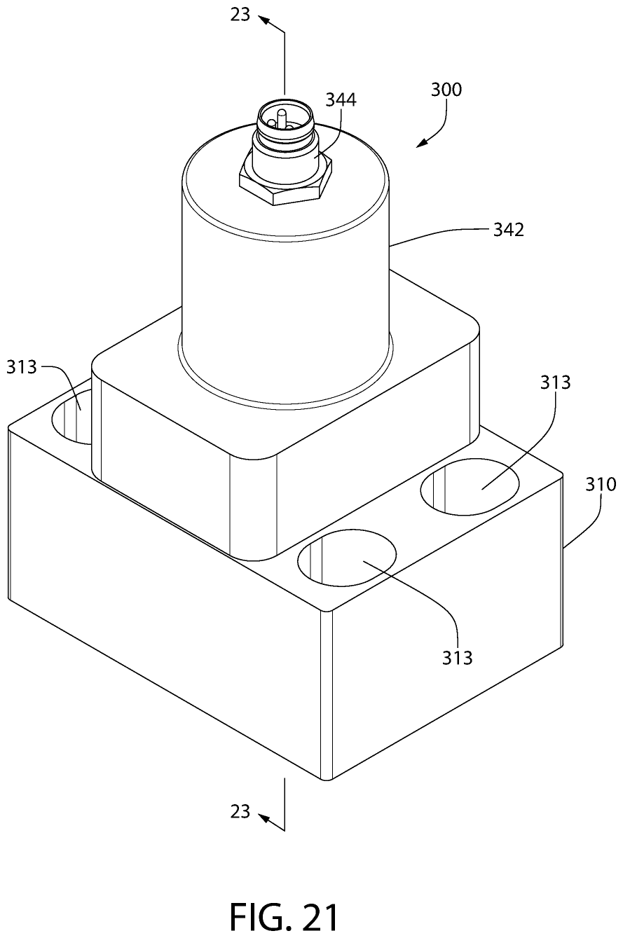

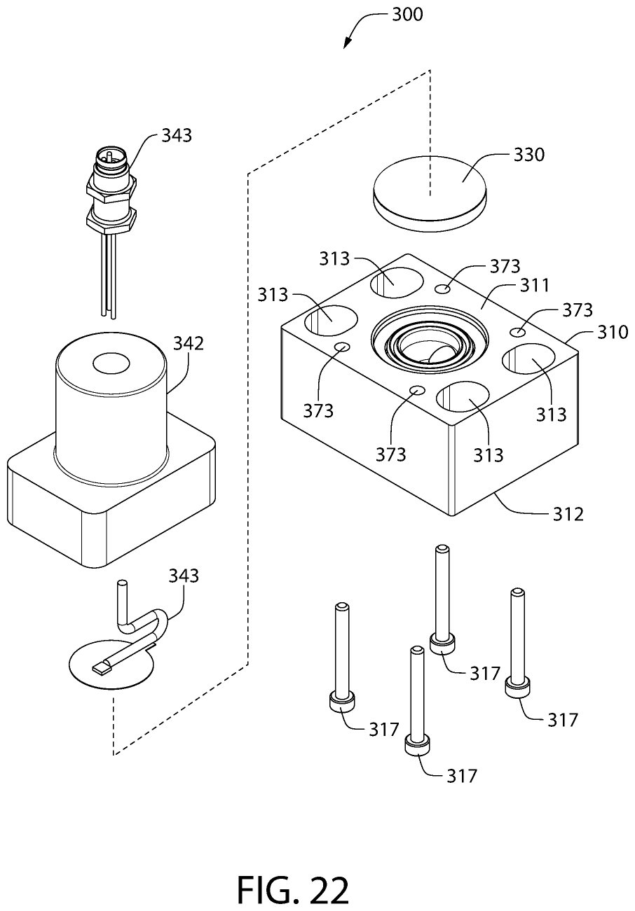

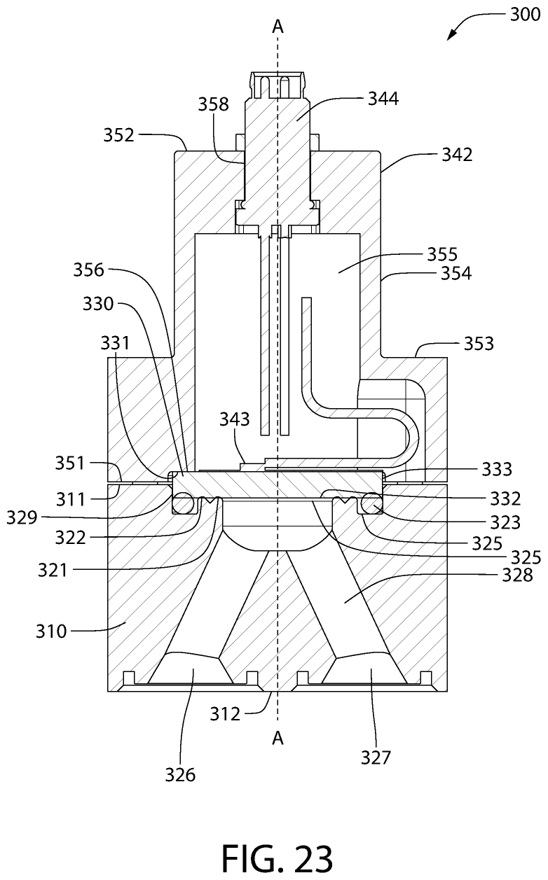

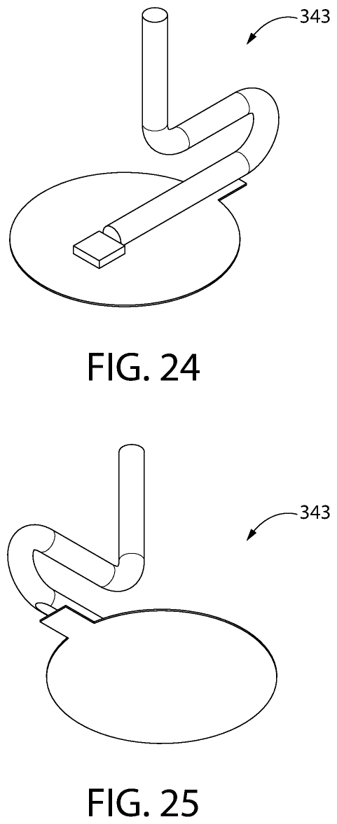

FIGS. 21 to 25 illustrate another embodiment of a fluid flow component 300. The fluid flow component 300 is configured as a temperature sensor utilizing a contact temperature sensor element instead of a non-contact temperature sensor element. The fluid flow component 300 is similar to the fluid flow component 200 except as discussed below. The fluid flow component 300 comprises a component base 310, a sensor housing 342, a connector 344, a sensing element 330, a sensor 343, and a plurality of fasteners 317.

The component base 310 has a top surface 311 and an opposite bottom surface 312. A sensing port 325 is formed in the top surface 311. The sensing port 325 receives the sensing element 330. A plurality of fastener passageways 313 are formed through the component base 310 to permit assembly of the fluid flow component 300 to another component or a substrate such as the support structure 1402, either directly or indirectly. Separately, a plurality of fastener passageways 373 are formed into the component base 310 to facilitate assembly of the component base 310 to the sensor housing 342. Both sets of fastener passageways 313, 373 may incorporate counter bores, countersinks, or other features to permit heads of fasteners to be recessed within the component base 310.

The component base 310 further incorporates a first port 326, a second port 327, and a flow path 328 extending from the first port 326 to the second port 327. The sensing port 325 is fluidly coupled to the flow path 328 between the first port 326 and the second port 327. A longitudinal axis A-A extends through the sensing port 325 and the flow path 328 is symmetrical with respect to the sensing port 325. In other embodiments, the flow path 328 may be asymmetrical with respect to the sensing port 325.

The sensing port 325 further comprises a first sealing rib 321, a second sealing rib 322 and a groove 324. Each of the first sealing rib 321, second sealing rib 322, and the groove 324 are symmetrical about the longitudinal axis A-A. An O-ring 323 is positioned within the groove 324. The first sealing rib 321, second sealing rib 322, and the O-ring 323 each engage a bottom surface 332 of the sensing element 330 to provide first, second, and third seals. An outer diameter 333 of the sensing element 330 is configured to fit within an outer wall 329 of the sensing port 325. The outer diameter 333 of the sensing element 330 may be smaller than the diameter of the outer wall 329 of the sensing port 325, or the outer diameter 333 may be an interference fit with the outer wall 329.

The sensor 343 is coupled to and in direct contact with a top surface 331 of the sensing element 330. This allows rapid measurement of the temperature of the sensing element 330, which is in direct contact with fluid flowing through the flow path 328. Thus, the sensor 343 accurately measures the temperature of the fluid in the flow path 328. Preferably, the sensor 343 is a rapid response type and the sensing element 330 is of a high thermal conductivity to ensure minimal error or delay in responding to changes in temperature. In other embodiments, the sensor 343 may monitor the temperature via infrared or other means. In these embodiments, the sensing element 330 may be transparent to electromagnetic waves and may or may not have a high thermal conductivity. In yet other embodiments, the sensor 343 may be a pressure sensor and may respond to deformation of the sensing element 330. As above, the sensing element 330 may be a thin layer of a material such as sapphire or it may be formed of a polymer such as PTFE.

The sensor housing 342 encloses the sensor 343 and receives the connector 344. The connector 344 is electrically connected to the sensor 343 and fits within a connector aperture 358 located at a distal end 352 of the sensor housing 342. The sensor housing 342 further comprises a flange 353 extending from a housing body 354. The flange 353 is located adjacent a base surface 351. The base surface 351 mates with the top surface 311 of the component base 310 and receives the fasteners 317 to couple the sensor housing 342 to the component base 310. The sensor housing 342 has a cavity 355 which receives the sensor 343, a portion of the connector 344, and a portion of the sensing element 330.

The sensor housing 342 also incorporates a clamping surface 356 which engages the top surface 331 of the sensing element 330, compressing the sensing element 330 against the first sealing rib 321, second sealing rib 322, and the O-ring 323 of the sensing port 325 and creating a fluid-tight connection between the sensing element 330 and the sensing port 325. Optionally, the top surface 311 of the component base 310 may be spaced from the base surface 351 of the sensor housing 341. Alternately, the top surface 311 may be in contact with the base surface 351.

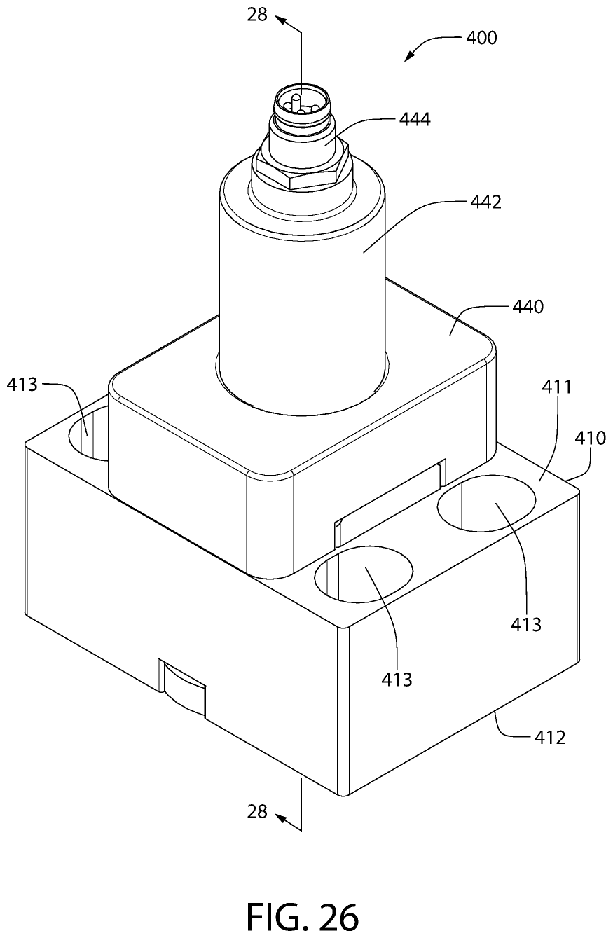

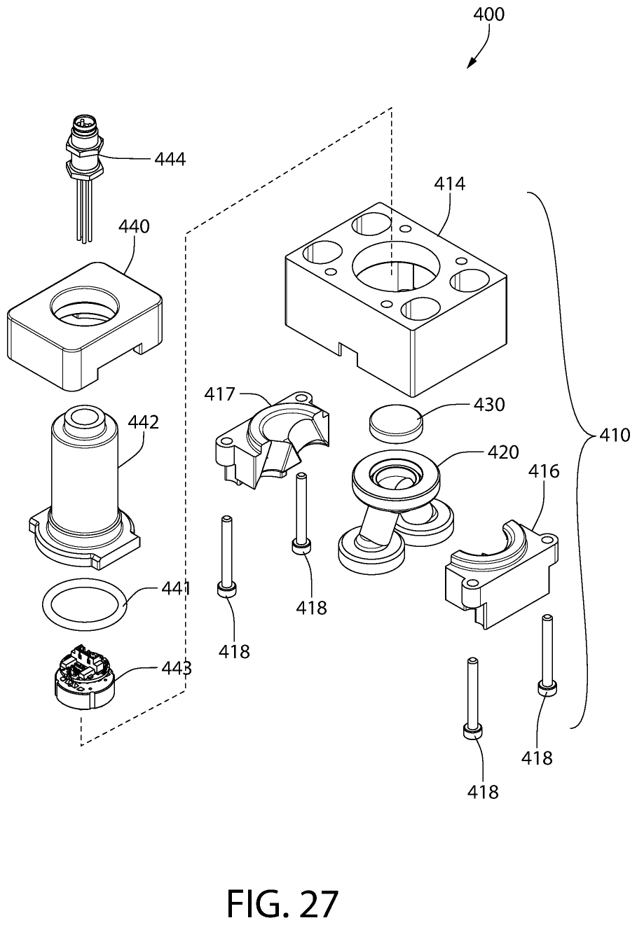

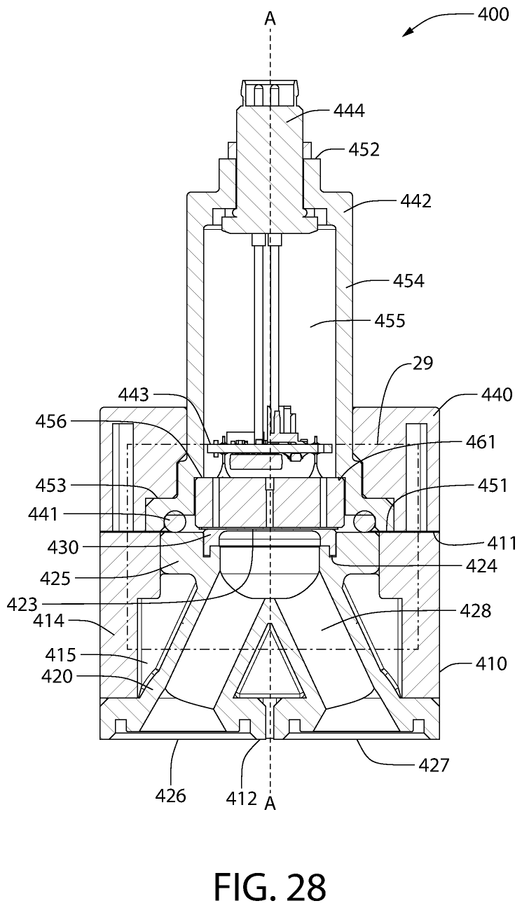

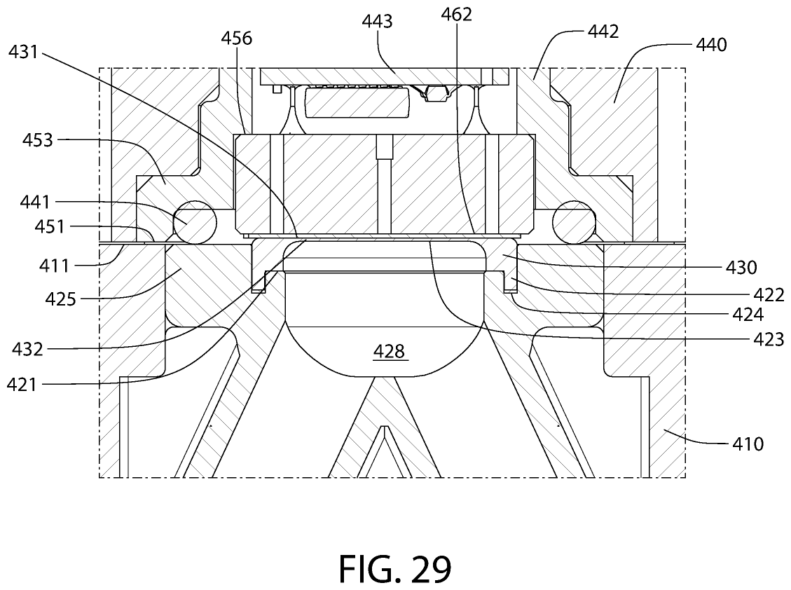

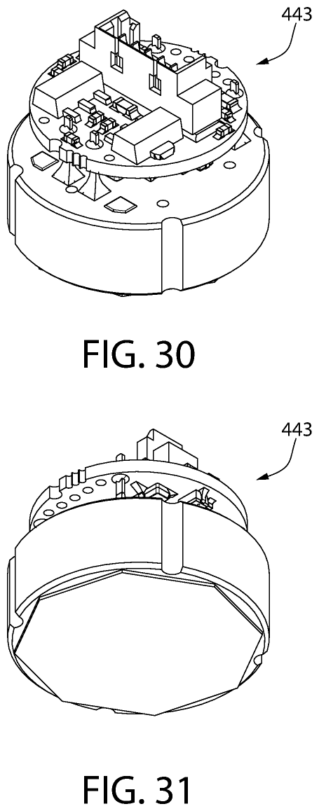

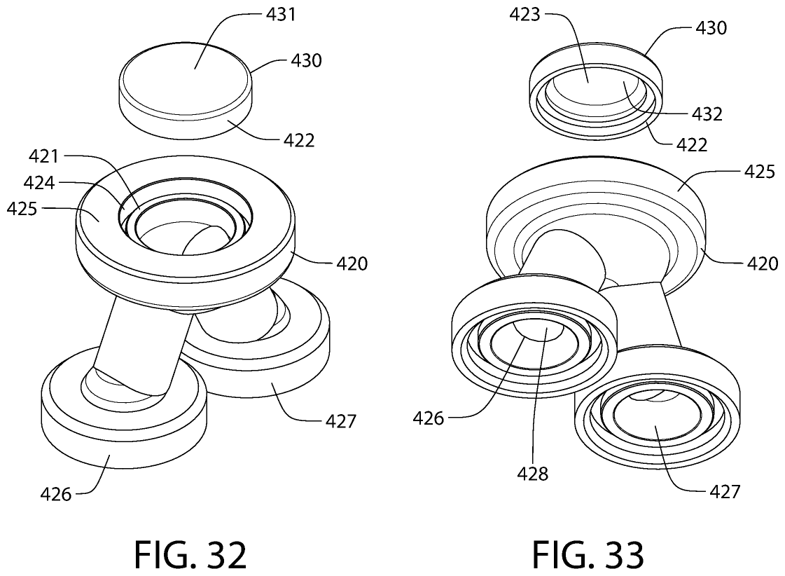

Turning to FIGS. 26 to 33, yet another embodiment of a fluid flow component 400 is disclosed. The fluid flow component 400 is configured as a pressure sensor configured to measure a pressure of the fluid within the fluid flow component 400. The fluid flow component 400 is generally similar to the fluid flow component 200 except as discussed below. The fluid flow component 400 comprises a component base 410, a retainer element 440, a sensor housing 442, a connector 444, a sensing element 430, a sensor 443, and a plurality of fasteners 417.

The component base 410 is an assembly formed of multiple components. The component base 410 has a top surface 411 and an opposite bottom surface 412. The component base 410 is formed as an assembly of an outer base 414, a first support portion 415, a second support portion 416, an insert 420, and a plurality of fasteners 417. As can be seen, the component base 410 is constructed from a plurality of separate components which enable flow of fluid through the fluid flow component 400. The insert 420 is surrounded by the first and second support portions 415, 416. The first and second support portions 415, 416 nest into the outer base 414 and are secured during assembly by the fasteners 417. This allows the component base 410 to be formed from a plurality of different components to optimize strength, cost, or other factors. For instance, the insert 420 may be formed of a material that is non-reactive to the fluids which will be utilized, while the other components may be formed of a material optimized for cost or other factors. In yet other embodiments, the component base 410 may be formed as a single component which is monolithic and integrally formed.

The fluid flow component 400 further comprises a sensing element 430, a sensor 443, an O-ring 441, the retainer element 440, the sensor housing 442, and the connector 444. The sensor housing 442 encloses the sensing element 430 and the O-ring 441. The connector 444 is also mounted partially within the sensor housing 442. The retainer element 440 secures the sensor housing 442 to the component base 410.

The connector 444 may be a panel mount connector, or any other type of connector which enables electrical connection with the sensor 443. The connector 444 is electrically connected to the sensor 443, enabling operation of the sensor 443 and allowing measurement of one or more properties of the fluid passing through the fluid flow component 400. The connector 444 may instead be replaced by a length of wire emerging from the sensor housing 442 instead of a panel mount or other electrical connector if so desired.

The sensor housing 442 extends from a base surface 451 to a distal end 452. The connector 444 is located in an aperture in the distal end 452 while the base surface 451 engages the top surface 411 of the component base 410. A flange 453 extends from the housing body 454 and forms a portion of the base surface 451. The flange 453 engages the retainer element 440. When the retainer element 440 is secured to the top surface 411 of the component base 410, the flange 453 is also pressed against the top surface 411 of the component base 410.

The sensor housing 442 further incorporates a cavity 455. The cavity 455 is configured to receive the sensing element 430 and sensor 443 as discussed above. The cavity 455 incorporates a clamping surface 456 which engages a shoulder surface 461 of the sensor 443. Thus, the clamping surface 456 of the sensor housing 442 is in direct physical contact with the shoulder surface 461 of the sensor 443. Thus, the sensor 443 is in direct physical contact with the clamping surface 456 of the sensor housing 442. The sensor housing 442 is further configured to have the clamping surface 456 at the same height as the clamping surface 256 of the sensor housing 242. This enables use of interchangeable parts in different assemblies because the sensor housing 242 is identical to the sensor housing 442.

The sensor 443 is compressed between the sensor housing 442 and the sensing element 430 by the interaction between the clamping surface 456 of the sensor housing 442 and the shoulder surface 461 of the sensor 443. The sensing element 430 has a top surface 431 and a bottom surface 432. A bottom surface 462 of the sensor 443 engages the top surface 431 of the sensing element 430, while the bottom surface 432 engages a sealing surface 421 of the insert 420. The sensing element 430 further comprises an annular ring 422 which engages a groove 424 formed into the sealing surface 421 of the insert 420. Thus, the annular ring 422 extends from the bottom surface 432 of the sensing element 430 and engages a groove 424 formed into the sealing surface 421 to provide a seal which prevents fluid leakage. Optionally, the groove 424 may be an interference fit with the annular ring 422 to facilitate sealing.

The sensor 443 compresses the sensing element 430 against the sealing surface 421 to provide sealing action. The sensing element 430 also comprises a diaphragm portion 423 which deflects in response to pressure from the fluid in the fluid flow component 400. The diaphragm portion 423 is surrounded by the annular ring 422 and deflects with respect to the annular ring 422. The sensing element 430 may be formed of a hard material such as sapphire, or in other embodiments, it may be formed of a polymer such as polytetrafluoroethane (“PTFE”) or another similar material. In the present embodiment, the sensing element 430 is formed as a disk having a non-constant thickness. The diaphragm portion 423 may range in thickness depending on design requirements. The top surface 431 of the sensing element 430 is in direct physical contact with the sensor 443 while the bottom surface 432 of the sensing element 430 is in direct physical contact with the sealing surface 421 of the insert 420.

The insert 420 has a sensing port 425, a first port 426, and a second port 427. The first and second ports 426, 427 may be either inlet or outlet ports for connecting fluid thereto. Thus, fluid may flow in either direction through a flow path 428 extending from the first port 426 to the second port 427. The sensing port 425 is fluidly coupled to the flow path 428 between the first port 426 and the second port 427. A longitudinal axis A-A extends through a center of the sensing port 425 such that the sensing port 425 is rotationally symmetric about the longitudinal axis A-A. The longitudinal axis A-A also extends through a center of the sensor housing 442, sensor 443, and sensing element 430. In the present embodiment, the flow path 428 is symmetrical with respect to the sensing port 425. Otherwise stated, reversing flow through the flow path 428 would not alter the path that fluid takes through the fluid flow component 400. In other embodiments, the flow path 428 need not be symmetrical and may be different between the first port 426 and the sensing port 425 as compared with the second port 427 and the sensing port 425.

The sensing port 425 of the insert 420 comprises the sealing surface 421 and the groove 424. Thus, the sealing surface 421 and the groove 424 form a portion of the sensing port 425 and may be altered depending on design requirements. This may include the pressure or material within the flow path 428, and may necessitate different sealing geometry to achieve the desired performance. The interface between the bottom surface 432 of the sensing element 430 and the sealing surface 421 forms a first seal. The interface between the annular ring 422 of the sensing element 430 and the groove 424 forms at least a second seal, but optionally a second, third and/or fourth seal on inner, bottom, and outer surfaces of the annular ring 422. Thus, at least two and as many as four distinct seals may be formed to ensure high resistance to leakage.

The insert 420 is similar to but not identical to the insert 220. The inserts 220, 420 may be formed by molding or other means. It is further contemplated that the inserts 220, 420 may be formed as identical unfinished blanks which are then finished with different geometry for the sensing ports 225, 425 to allow different sensing elements 230, 430 to be utilized without requiring additional production tooling such as molds. This finishing may be performed via machining of the sensing ports 225, 425 to achieve the appropriate geometry for the type of sensing element which will be utilized in the fluid flow component.

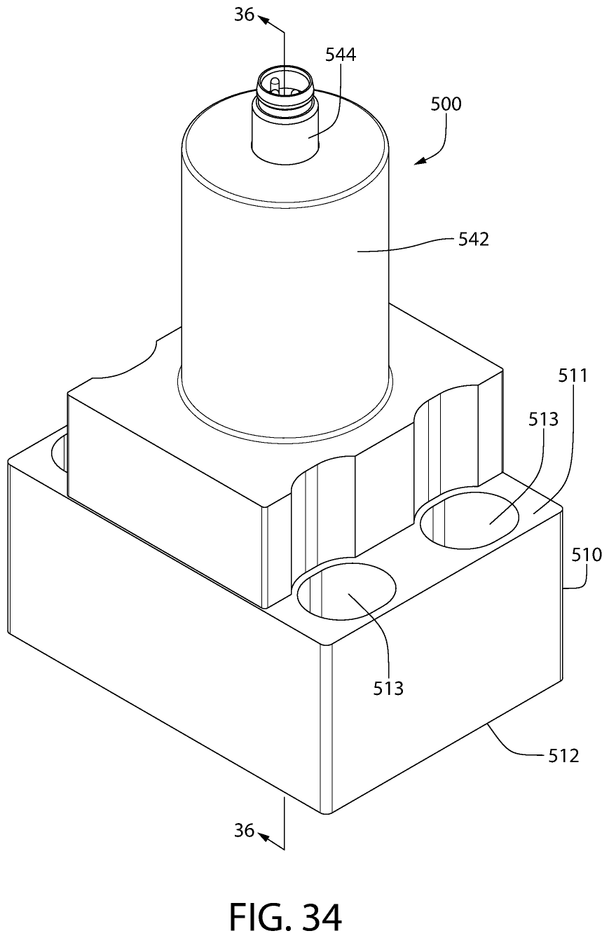

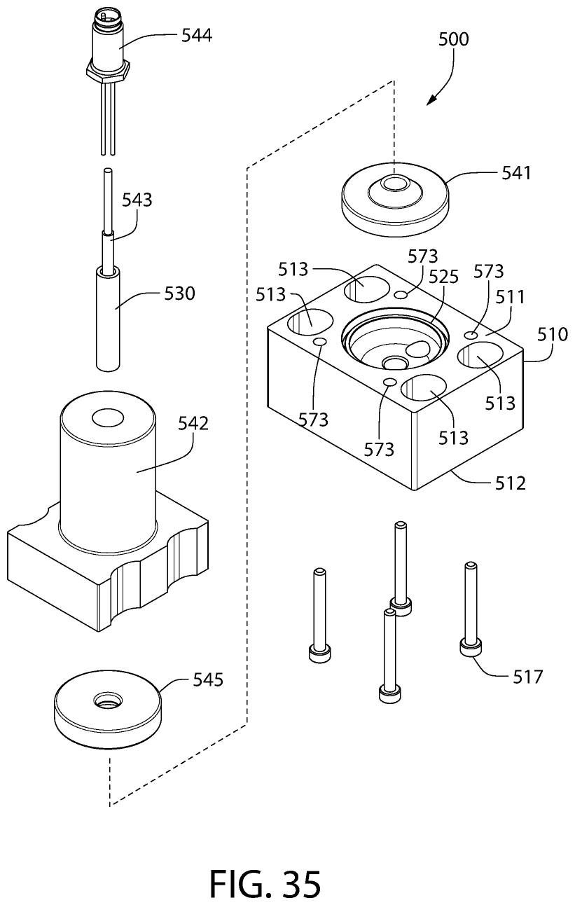

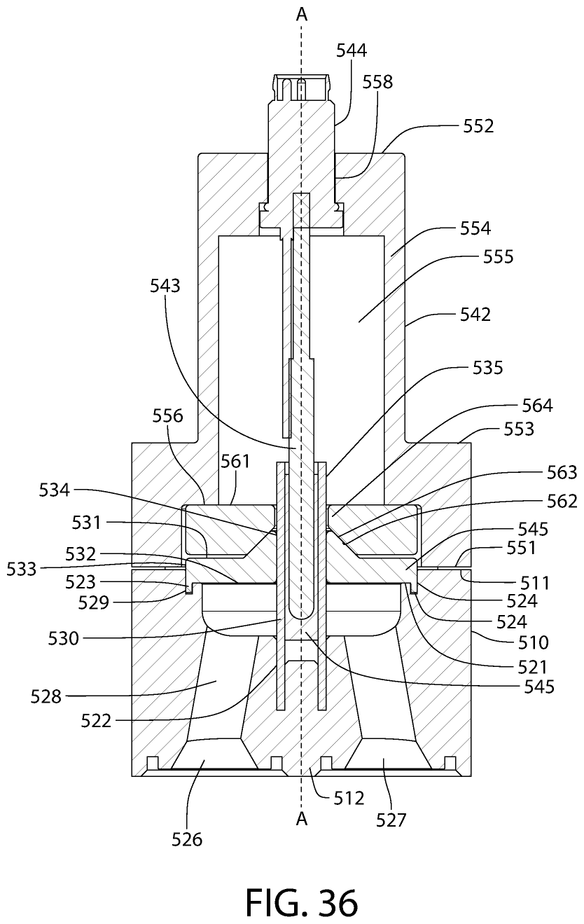

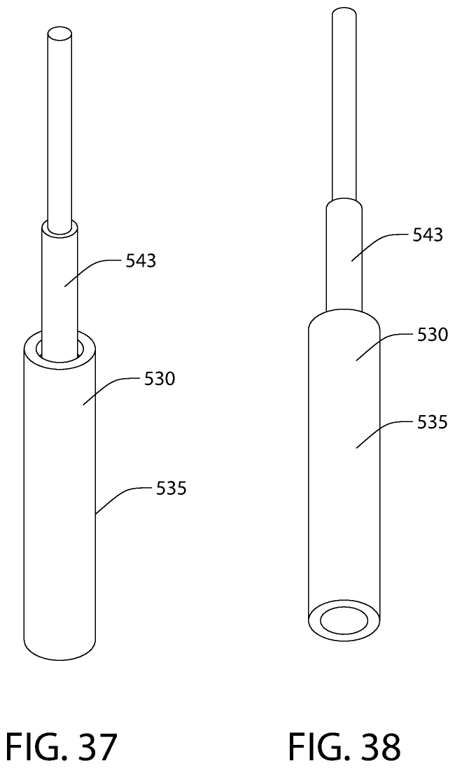

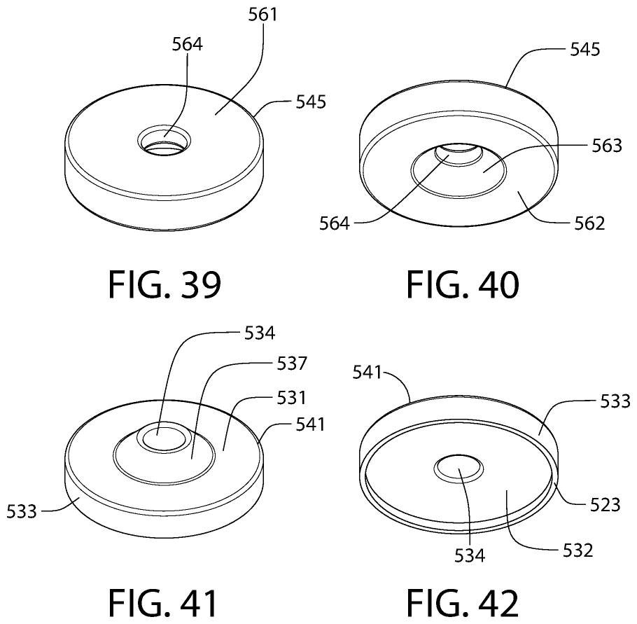

FIGS. 34 to 42 illustrate yet another embodiment of a fluid flow component 500 configured to measure temperature of a fluid. The fluid flow component 500 is configured as a temperature sensor utilizing a contact temperature sensor element in a configuration generally referred to as a “thermowell” because the sensor is immersed in fluid. The fluid flow component 500 comprises a component base 510, a sensor housing 542, a connector 544, a sensing element 530, a sensor 543, a spacer 545, a seal 541, and a plurality of fasteners 517.

The component base 510 has a top surface 511 and an opposite bottom surface 512. A sensing port 525 is formed in the top surface 511. The sensing port 525 receives the sensing element 530. A plurality of fastener passageways 513 are formed through the component base 510 to permit assembly of the fluid flow component 500 to another component or a substrate such as the support structure 1402, either directly or indirectly. Separately, a plurality of fastener passageways 573 are formed into the component base 510 to facilitate assembly of the component base 510 to the sensor housing 542. Both sets of fastener passageways 513, 573 may incorporate counter bores, countersinks, or other features to permit heads of fasteners to be recessed within the component base 510.

The component base 510 further incorporates a first port 526, a second port 527, and a flow path 528 extending from the first port 526 to the second port 527. The sensing port 525 is fluidly coupled to the flow path 528 between the first port 526 and the second port 527. A longitudinal axis A-A extends through the sensing port 525 and the flow path 528 is symmetrical with respect to the sensing port 525. In other embodiments, the flow path 528 may be asymmetrical with respect to the sensing port 525.

The sensing port 525 further comprises a sealing surface 521 and a groove 524. The sealing surface 521 and the groove 524 are symmetrical about the longitudinal axis A-A. An annular ring 523 of the seal 541 is positioned within the groove 524. The annular ring 523 of the seal 541 extends from a bottom surface 532 of the seal 541 into the groove 524. The sealing surface 521, engages the bottom surface 532 of the seal 541 to provide a first seal. The interface between the annular ring 523 and the groove 524 may result in second, third, or fourth seals along the inner, bottom, and outer surfaces of the annular ring 523 and corresponding surfaces of the groove 524. An outer diameter 533 of the seal 541 is configured to fit within an outer wall 529 of the sensing port 525. The outer diameter 533 of the seal 541 may be smaller than the diameter of the outer wall 529 of the sensing port 525, or the outer diameter 533 may be an interference fit with the outer wall 529. The outer diameter 533 of the seal 541 may be the same as the outer surface of the annular ring 523 or it may be a separate surface.

The sensor 543 is inserted within the sensing element 530. Typically, the sensor 543 is potted within a potting material 545 which may be an epoxy or other material which provides a high degree of thermal conductivity between the sensing element 530 and the sensor 543. This allows rapid measurement of the temperature of the fluid surrounding the sensing element 330, the fluid flowing through the flow path 528. Thus, the sensor 543 accurately measures the temperature of the fluid in the flow path 528. Preferably, the sensor 543 is a rapid response type and the sensing element 530 is of a high thermal conductivity to ensure minimal error or delay in responding to changes in temperature. In other embodiments, the sensor 543 may monitor the temperature via infrared or other means. In these embodiments, the sensing element 530 may be transparent to electromagnetic waves and may or may not have a high thermal conductivity. In yet other embodiments, the sensor 543 may be a pressure sensor and may respond to deformation of the sensing element 530. As above, the sensing element 530 may be formed of a tube of a material such as sapphire or it may be formed of a polymer such as PTFE.

Preferably, the sensing element 530 is a hollow tube which extends from a pocket 522 formed in the sensing port 525 through an aperture 534 formed in the seal 541 and extending from a top surface 531 of the seal 541 to the bottom surface 532 of the seal 541. Thus, the sensing element 530 has an outer surface 535 which is in contact with the aperture 534 of the seal 541. The sensing element 530 extends through the flow path 528 and is surrounded by fluid within the flow path 528 at the location of the sensing port 525. The aperture 534 forms a fluid-tight connection with the outer surface 535 of the sensing element 530 and may be an interference fit or may be bonded via adhesives, ultrasonic welding, or other joining processes known in the art. The pocket 522 need not be an interference fit with the outer surface 535 of the sensing element 530 because the potting material 545 may seal the sensor 543. Alternately, the pocket 522 may be an interference fit with the outer surface 535 of the sensing element 530 or the sensing element 530 may be joined via a bonding technique discussed above in order to prevent fluid from contacting the potting material 545 or to facilitate assembly.

The sensor housing 542 encloses portions of the sensor 543 and the sensing element 530 and receives the connector 544. The connector 544 is electrically connected to the sensor 543 and fits within a connector aperture 558 located at a distal end 552 of the sensor housing 542. The sensor housing 542 further comprises a flange 553 extending from a housing body 554. The flange 553 is located adjacent a base surface 551. The base surface 551 mates with the top surface 511 of the component base 510 and receives the fasteners 517 to couple the sensor housing 542 to the component base 510. The base surface 551 may either be in contact with the top surface 511 or spaced from the top surface 511. The sensor housing 542 further includes a cavity 555 which receives a portion of the sensor 543, a portion of the connector 544, and a portion of the sensing element 530.

The sensor housing 542 also incorporates a clamping surface 556 which engages the shoulder surface 561 of the spacer 545. The direct contact between the clamping surface 556 of the sensor housing 542 and the shoulder surface 561 of the spacer 545 ensures that the seal 541 is compressed against the sensing port 525. The bottom surface 562 of the spacer 545 engages the top surface 531 of the seal 541. The top surface 531 may have a protruding conical surface 537 which engages a recessed conical surface 563 on the bottom surface 562 of the spacer 545. An aperture 564 is formed through the spacer 545 to permit passage of the sensing element 530 and the sensor 543. The aperture 564 is preferably sized to be a free fit with the sensing element 530. In other embodiments, the spacer 545 may be omitted and the seal 541 may engage the clamping surface 556 of the sensor housing 542.

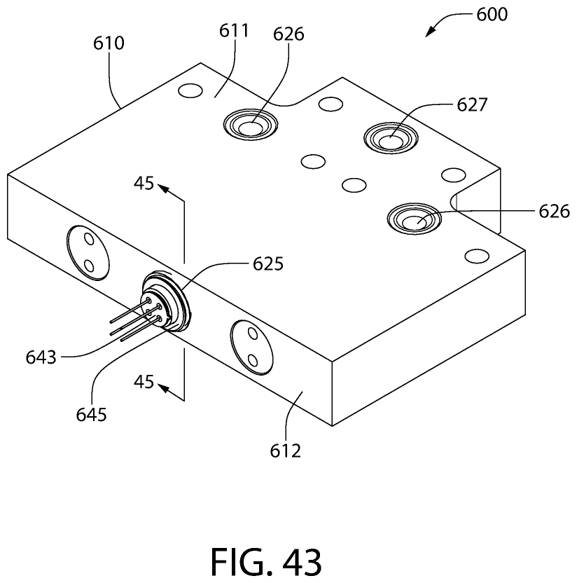

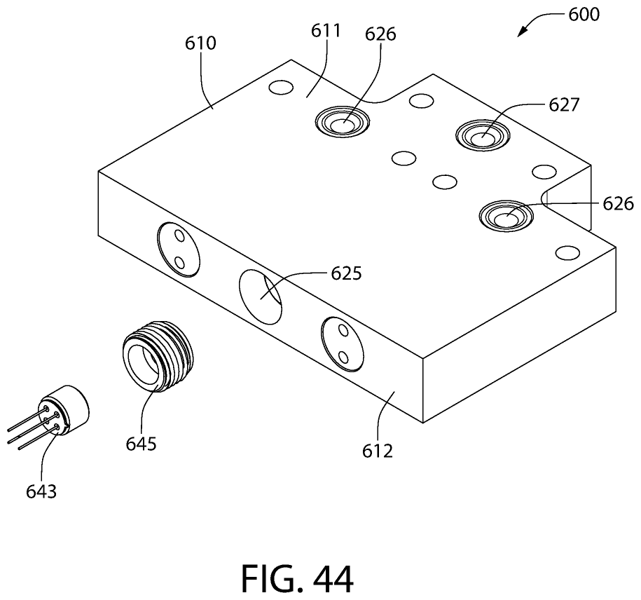

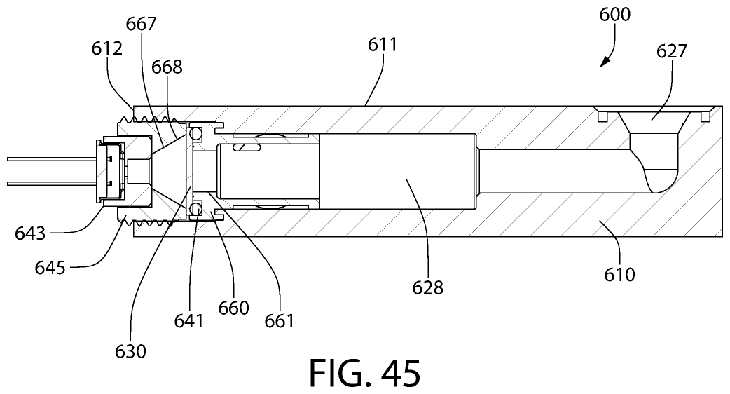

FIGS. 43 to 45 illustrate a fluid flow component 600 that takes the form of a fluid mixer as well as a temperature sensor. The fluid flow component 600 comprises a component base 610, a sensor 643, a spacer 645, a sensing element 630, an O-ring 641, and a mixing element 660. The component base 610 has a top surface 611 and a front surface 612. The top surface 611 incorporates two first ports 626 and one second port 627. The two first ports 626 and the second port 627 are fluidly coupled via a flow path 628 within the component base 610. A sensing port 625 is formed in the front surface 612 and fluidly connected to the flow path 628 between the first ports 626 and the second port 627.

The mixing element 660 is inserted into the sensing port 625, the mixing element 660 having an aperture 661 which extends through the mixing element 660. In typical operating modes, fluid flows through the first ports 626, through the mixing element 660, and out of the second port 627. As the fluid flows through the mixing element 660, the temperature or pressure may be measured by the sensor 643 via the aperture 661 in the mixing element 660. The O-ring 641 engages the sensing element 630 and the mixing element 660 to seal the sensing port 625. The sensing element 630 may be optically transparent like the sensing element 230, and may be formed of sapphire or a polymeric material to permit sensing properties such as temperature or pressure of the fluid within the fluid flow component 600.

The spacer 645 incorporates threads which engage corresponding threads in the sensing port 625, the spacer 645 also having a conical inner surface 668 and an aperture 667 that extends through the spacer 645. The sensor 643 is configured to monitor the temperature of the fluid through the aperture 667 of the spacer 645, through the sensing element 630, and through the aperture 661 in the mixing element 660. The sensing element 630 is clamped by the spacer 645 and the sensor 643 is coupled to the spacer 645.

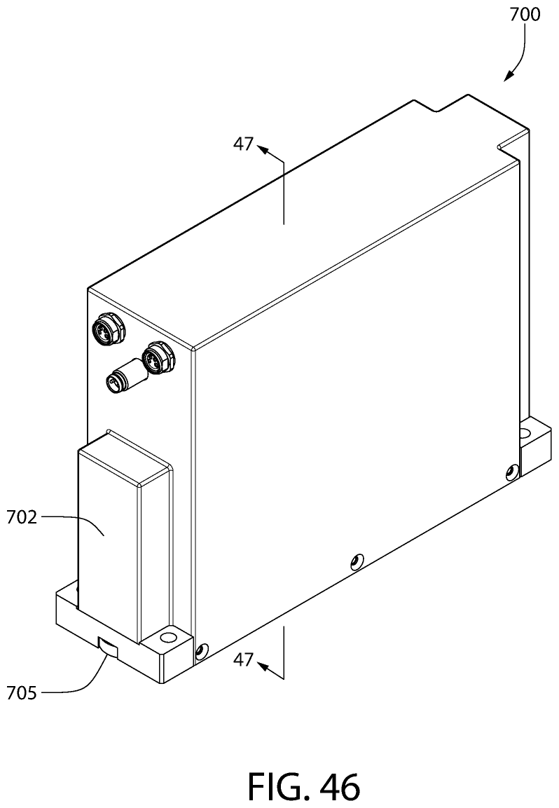

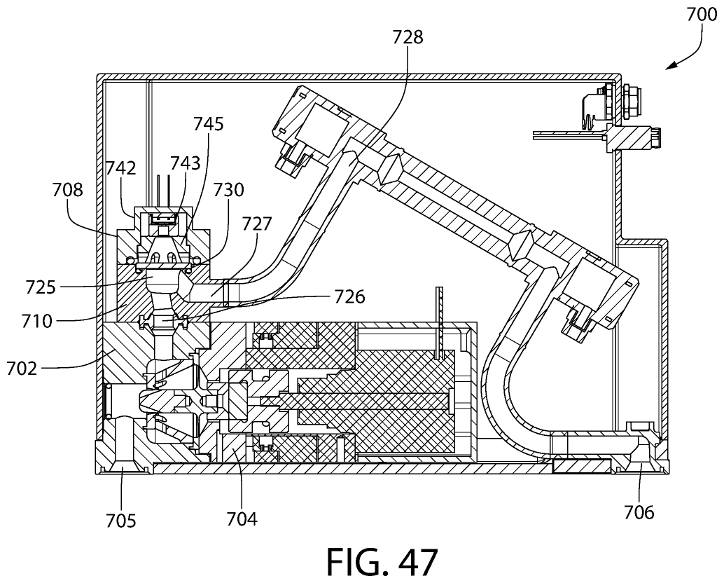

FIGS. 46 and 47 illustrate yet another fluid flow component 700 which includes a component assembly 702 formed of a plurality of separate components. The component assembly 702 comprises a valve assembly 704 and a sensing assembly 708 comprising a component base 710. A valve assembly 704 and the sensing assembly 708 are operably coupled to a flow path 728 extending from a first port 705 in the component assembly 702 to a second port 706 in the component assembly 702. Within the component base 710 of the sensing assembly 708, the flow path 728 extends from a first port 726 to a second port 727. In addition, the component base 710 incorporates a sensing port 725 fluidly coupled to the flow path 728.

The sensing assembly 708 further incorporates a sensor housing 742, a sensor 743, a spacer 745, and a sensing element 730. The sensing element 730 seals the sensing port 725 in the component base 710. The sensing element 730 is sealed against the sensing port 725 via pressure from the spacer 745, which in turn is compressed by pressure from the sensor housing 742. The sensor housing 742 further encloses the sensor 743. Thus, the sensor is in direct contact with the spacer 745. The spacer 745 is in direct contact with the sensing element 730, which in turn is in direct contact with the sensing port 725 of the component base 710.

In yet another implementation, a method of manufacturing articles may be employed. First, a fluid delivery module 1400 is provided, the fluid delivery module 1400 having an inlet 102 and an outlet 104. A flow passage extends from the inlet 102 to the outlet 104. A fluid flow component 200 forms a part of the fluid delivery module 1400. The fluid flow component has an inlet port 226, an outlet port 227, and a flow path 228 extending from the inlet port 226 to the outlet port 227. The flow path 228 forms a portion of the flow passage extending from the inlet 102 to the outlet 104.

Second, a process fluid is supplied from a fluid supply 1010 to the inlet 102 of the fluid delivery module 1400. Third, the process fluid is flowed through the flow passage and through the flow path 228 of the fluid flow component 200. The process fluid is flowed through the flow path 228 and the remainder of the flow passage to the outlet 104 of the fluid delivery module 1400. The outlet 104 is fluidly coupled to an outlet manifold 401.

Fourth, a property of the process fluid is measured via a sensing port 225, the sensing port 225 being in fluid communication with the flow path 228 of the fluid flow component 200. The sensing port 225 is located between the inlet port 226 and the outlet port 227 and is sealed by a sensing element 230. A sensor 243 is operably coupled to the sensing element 230 so that the sensor 243 can measure the property of the process fluid through the sensing element 230. This can be done through observation of infrared or other electromagnetic waves, contact temperature measurement, deflection of the sensing element 230, or any other known means.

Fifth, the process fluid is delivered from the outlet 104 of the fluid delivery module 1400 to a processing chamber 1300 via the outlet manifold 401. The outlet manifold 401 is fluidly coupled to the processing chamber 1300. Sixth, a process is performed on an article within the processing chamber. This may be any known process achieved by applying one or more fluids to a substrate. For instance, the fluid may be a sulfuric acid solution and the substrate may be a wafer made of silicon or another material.

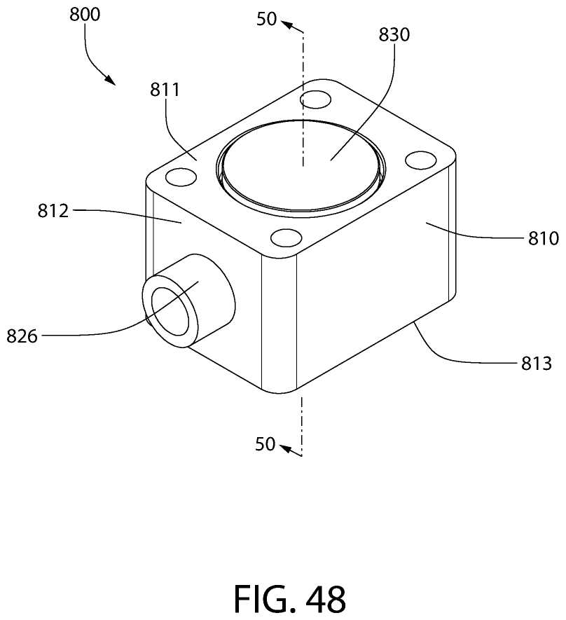

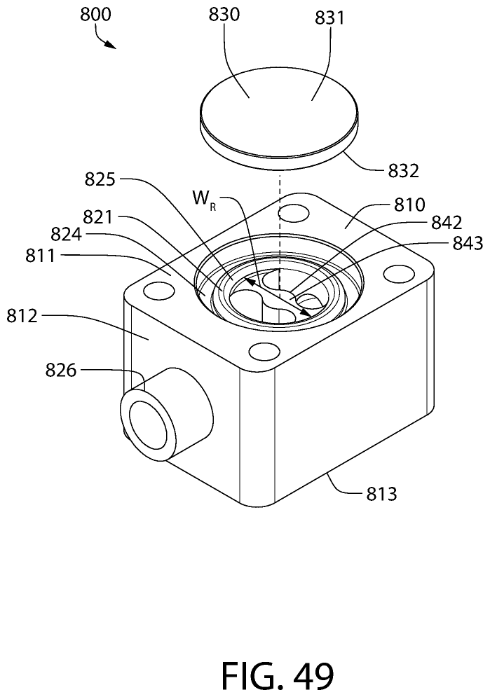

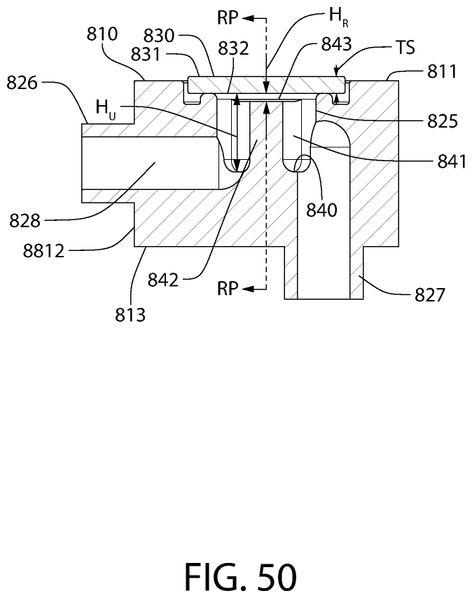

FIGS. 48 to 50 illustrate a portion 800 of a fluid flow component that measures temperature of a process fluid. The portion 800 of the fluid flow component comprises a component base 810 and a sensing element 830. A flow path 828 extends from an inlet port 826 to an outlet port 827. The flow path 828 enters a sensing port 825, the sensing port 825 being fluidly coupled to the flow path 828 between the inlet port 826 and the outlet port 827. The sensing port 825 comprises a sealing rib 821 and a groove 824. The sensing port 825 also has a floor 840 and a wall 841 extending from the floor 840 to the sensing element 830. Finally, a restriction element 842 extends from the floor 840 toward the sensing element 830. The restriction element 842 extends along a restriction plane RP which is transverse to the flow path 828.

The sensing element 830 has a top surface 831 and a bottom surface 832. The bottom surface 832 fits within the sensing port 825 and engages the sealing rib 821. Optionally, an O-ring may be installed in the groove 824 to provide additional sealing of the sensing element 830. The sensing element 830 has a sensing thickness T_{S} measured from the top surface 831 to the bottom surface 832. A restriction height H_{R} extends along the restriction plane RP and is measured between the bottom surface 832 of the sensing element 830 and a top surface 843 of the restriction element 842. Separately, a restriction width W_{R} extends along the restriction plane RP and is measured between opposite sides of the wall 841 of the sensing port 825. Thus, the area defined by the restriction height H_{R} and the restriction width W_{R} determines a restriction area through which the fluid must flow.

Separately, an unrestricted height H_{U} is measured between the bottom surface 832 of the sensing element 830 and the floor 840 of the sensing port 825. The unrestricted height H_{U} does not extend along the restriction plane RP, but is parallel to the restriction plane RP and measured at a location either upstream or downstream of the restriction element 842. The unrestricted height H_{U} is greater than the restriction height H_{R}. Otherwise stated, the unrestricted height H_{U} is measured to a floor of the flow path 825.

The component base 810 has a top surface 811, a front surface 812, and a bottom surface 813. The sensing port 825 is formed into the top surface 811. The inlet port 826 is formed in the front surface 812. The outlet port 827 is formed in the bottom surface 813. Optionally, the inlet and outlet ports 826, 827 may be arranged such that they are formed into the same surface, opposite surfaces, or any other configuration. The inlet port 826 and outlet port 827 are configured as tube extensions that are configured to receive a connector or tube. Optionally, the connector or tube may be welded to the tube extensions of the inlet port 826 or the outlet port 827. In alternate configurations, the inlet port 826 and outlet port 827 may incorporate a seal cavity or other feature configured to receive a seal. Optionally one or both of the inlet port 826 and the outlet port 827 may be configured to accept a seal while the other one of the inlet port 826 and the outlet port 827 may be configured to incorporate a tube extension.

In the present embodiment, the sensing thickness TS of the sensing element 830 may range from 0.5 mm to 2.0 mm. For instance, the sensing thickness TS may be 0.5 mm, 1.0 mm, or 2.0 mm. The restriction height H_{R} may range from 0.5 mm to 3.0 mm. For example, the restriction height H_{R} may be 0.5 mm, 1.0 mm, 1.5 mm, 2.0 mm, or 3.0 mm. The restriction width W_{R} is 12.0 mm, but may be different in other embodiments. The unrestricted height H_{U} is 9.5 mm, but it may be different in other embodiments. The present embodiment illustrates a restriction height H_{R} of 1.0 mm.

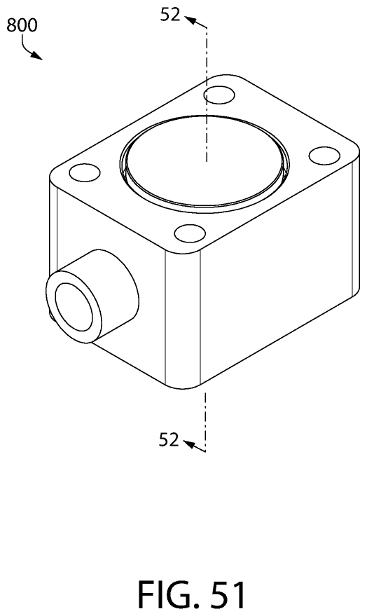

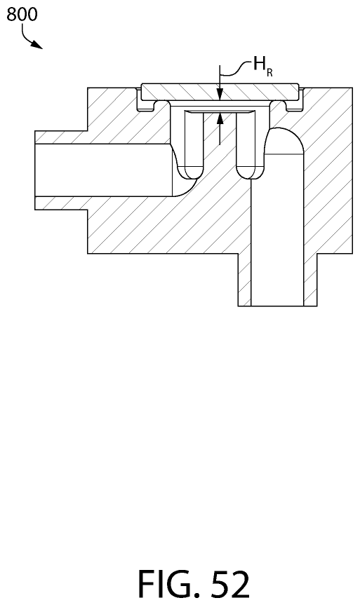

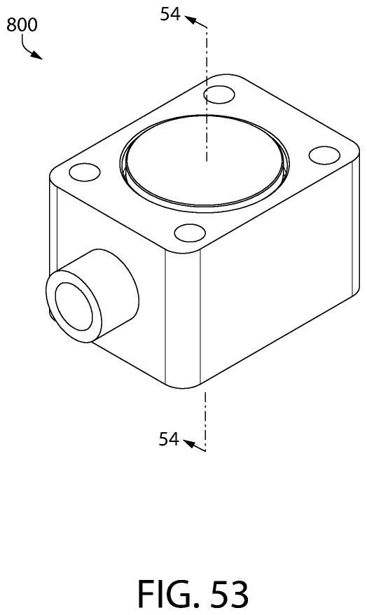

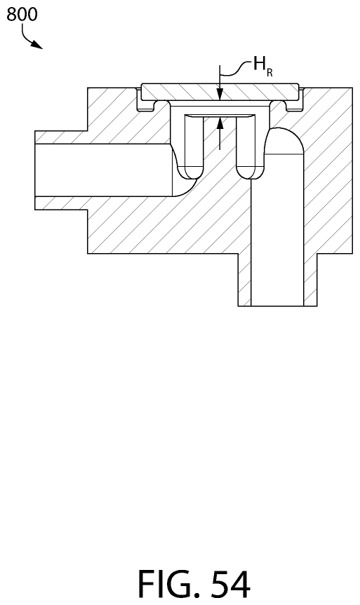

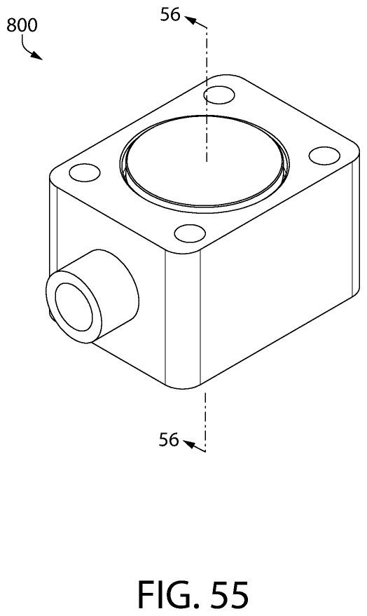

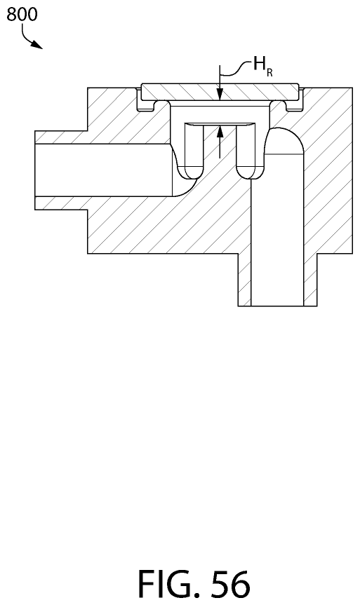

Turning to FIGS. 51-56, additional portions 800 are illustrated. The portions 800 illustrated in FIGS. 51-56 are substantially identical to the portion 800 illustrated in FIGS. 48-50, but each embodiment has a different restriction height H_{R}. The embodiment of FIGS. 51 and 52 has a restriction height H_{R} of 1.5 mm. The embodiment of FIGS. 53 and 54 has a restriction height H_{R} of 2.0 mm. The embodiment of FIGS. 55 and 56 has a restriction height H_{R} of 3.0 mm.

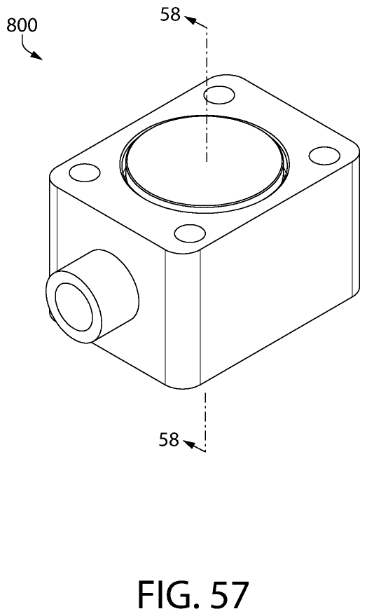

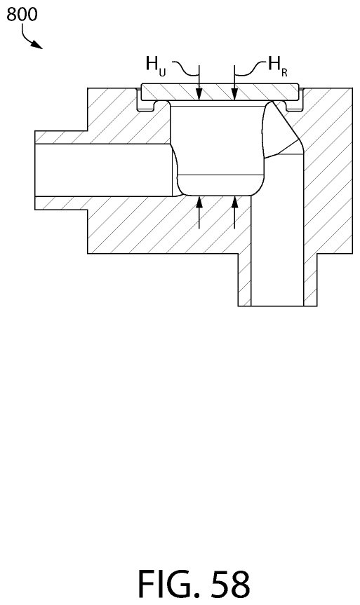

FIGS. 57 and 58 illustrate a portion 800 where the restriction element 842 is omitted. The portion 800 of FIGS. 57 and 58 is identical to the portion 800 of FIGS. 48-50 with the exception of a restriction height H_{R} which is equal to the unrestricted height H_{U} as a result of the elimination of the restriction element 842.

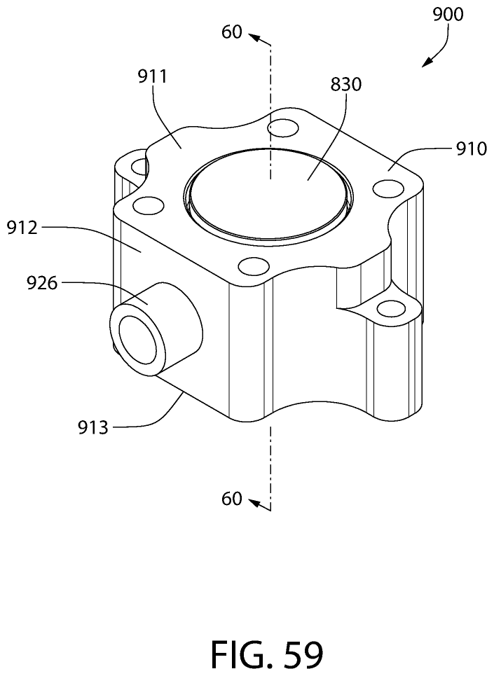

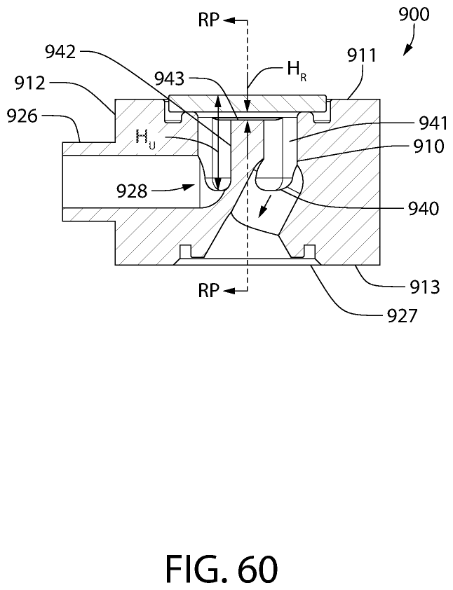

FIGS. 59 and 60 illustrate a portion 900. The portion 900 is generally similar to the portion 800 except as discussed. The portion 900 has a component base 910 and a sensing element 830. The component base 910 has a distinct shape from the component base 810 of the embodiments of FIGS. 48-58. The component base 910 has a distinct exterior shape, but incorporates an analogous flow path configuration. A flow path 928 extends from an inlet port 926 to an outlet port 927. A sensing port 925 is located between the inlet port 926 and the outlet port 927. The sensing port 925 has a floor 940 and a wall 941 extending from the floor 940 to the sensing element 830. Finally, a restriction element 942 extends from the floor 940 toward the sensing element. The restriction element 942 extends along a restriction plane RP which is transverse to the flow path 928.

A restriction height H_{R} extends along the restriction plane RP and is measured between a bottom surface 832 of the sensing element 830 and a top surface 943 of the restriction element 942. An unrestricted height H_{U} is measured between the bottom surface 832 of the sensing element 830 and the floor 940 of the sensing port 925. The unrestricted height H_{U} does not extend along the restriction plane RP, but is parallel to the restriction plane RP and measured at a location either upstream or downstream of the restriction element 942. The unrestricted height H_{U} is greater than the restriction height H_{R}. Otherwise stated, the unrestricted height H_{U} is measured to a floor of the flow path 925.

The component base 910 has a top surface 911, a front surface 912, and a bottom surface 913. The sensing port 925 is formed into the top surface 911. The inlet port 926 is formed in the front surface 912. The outlet port 927 is formed in the bottom surface 913. Optionally, the inlet and outlet ports 926, 927 may be arranged such that they are formed into the same surface, opposite surfaces, or any other configuration. The inlet port 926 is configured as a tube extension that is configured to receive a connector or tube. The outlet port 927 has a seal cavity which is configured to receive a seal, the seal allowing joining of two different surfaces. Optionally, the inlet port 927 may incorporate a seal cavity configured to receive a seal while the outlet port 927 may be a tube stub configured to receive a connector or tube.

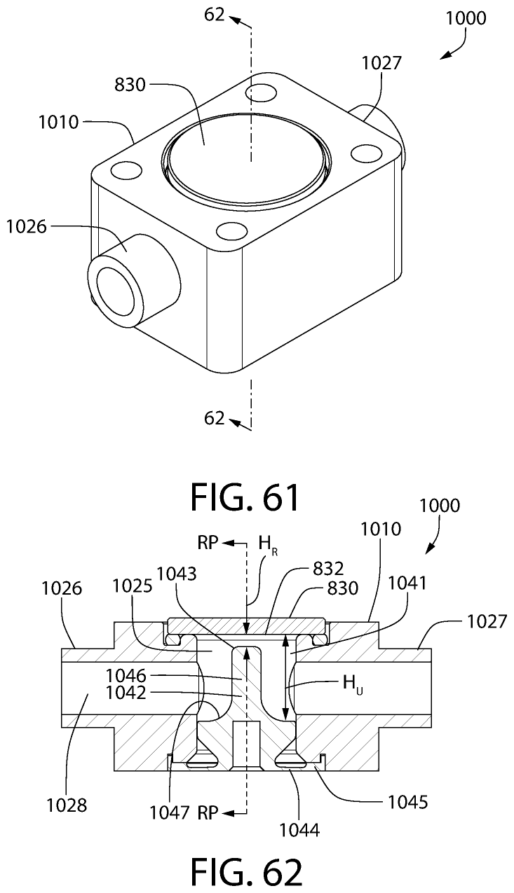

Turning to FIGS. 61-64, an additional portion 1000 is illustrated. The portion 1000 is configured to allow adjustment of the restriction height H_{R}. The portion 1000 incorporates a component base 1010, a sensing element 830, and a restriction element 1042. The component base 1010 has a flow path 1028 extending from an inlet port 1026 to an outlet port 1027. A sensing port 1025 is located between the inlet port 1026 and the outlet port 1027 along the flow path 1028. The sensing port 1025 has a wall 1041 that extends from a bottom surface 832 of the sensing element to the restriction element 1042.

The restriction element 1042 has a top surface 1043, a movable portion 1046, a diaphragm 1044, and a fixed portion 1045. The rigid portion 1045 fits within a corresponding cavity in the sensing port 1025 and provides a fluid tight seal with the component base 1010. The diaphragm 1044 is configured to permit movement of the movable portion 1046 with respect to the fixed portion 1045. The top surface 1043 is located on the fixed portion 1045 and defines a restriction height H_{R} between the top surface 1043 and the bottom surface 832 of the sensing element 830. Separately, an unrestricted height H_{U} is defined between a floor 1047 of the movable portion 1046 and the bottom surface 832 of the sensing element 830. The restriction height HR is measured along a restriction plane RP which extends perpendicular to the flow path 1028 and intersects the sensing element 830 and the top surface 1043 of the restriction element 1042.

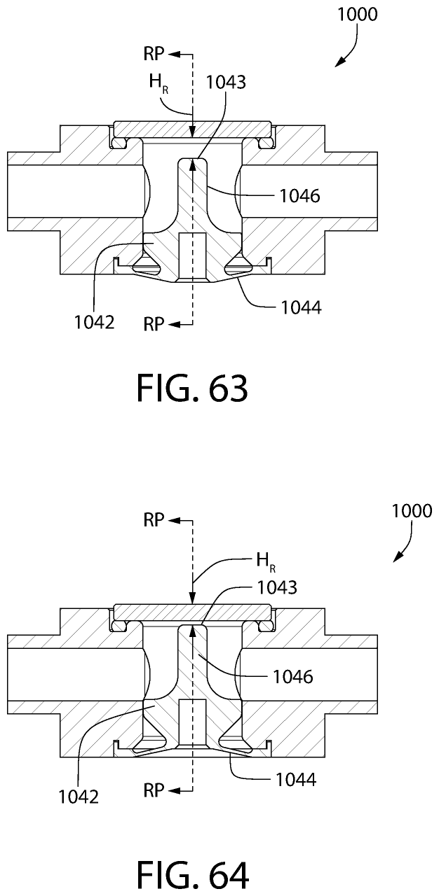

FIG. 62 illustrates the portion 1000 in a neutral state, whereby the diaphragm 1044 is in the middle of its range of motion. In this condition, the restriction height H_{R} may be 2.0 mm or another value approximately halfway between its maximum and minimum values. FIG. 63 illustrates the portion 1000 in a retracted state. In this condition, the diaphragm 1044 is deflected such that the restriction height H_{R} may be 3.0 mm or greater. FIG. 64 illustrates the portion 1000 in an extended state. In this condition, the diaphragm 1044 is deflected such that the restriction height H_{R} may be 0.5 mm or less. The restriction element 1042 may be operated by an actuator such as a solenoid or other linear actuator. The restriction element 1042 may be controlled by applying a force to the movable portion 1046 to achieve the desired restriction height H_{R}. As will be discussed in greater detail below, varying the restriction height H_{R} may achieve improved response times for the resulting fluid flow component, allowing faster temperature measurements or reduced restriction to fluid flow depending on operating parameters such as mass or volume flow rates of the fluid flowing therethrough.

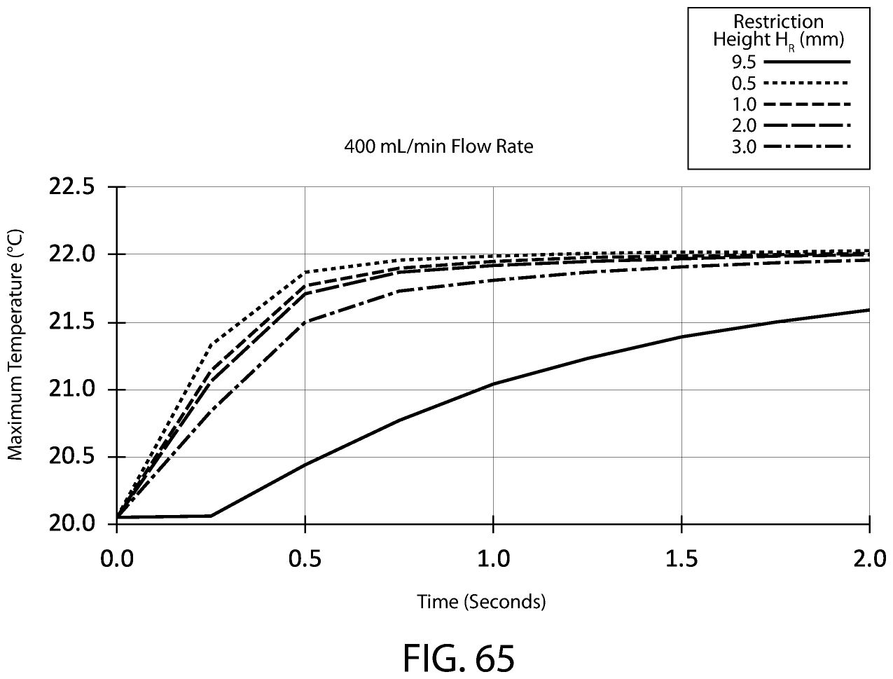

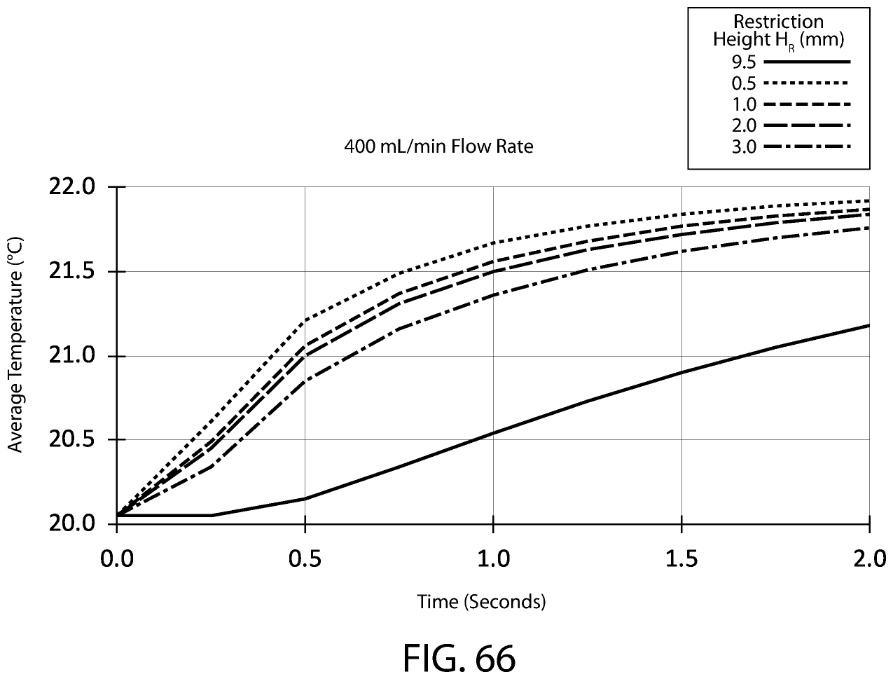

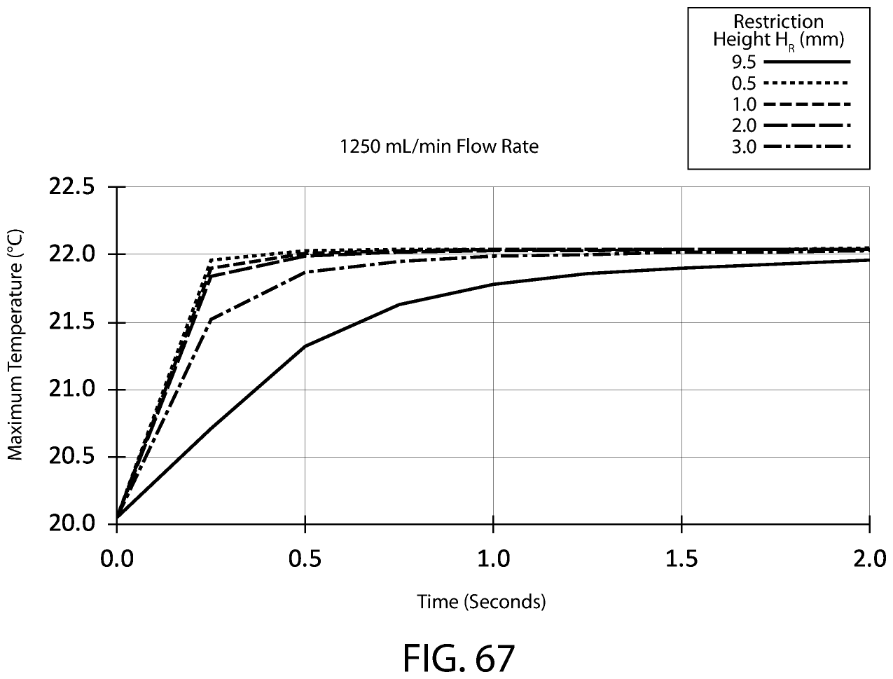

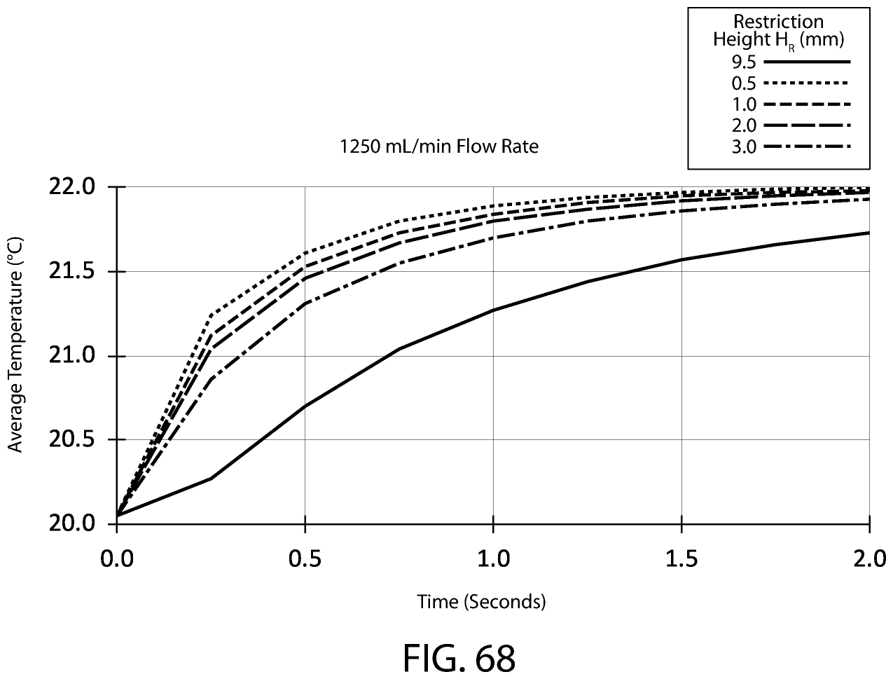

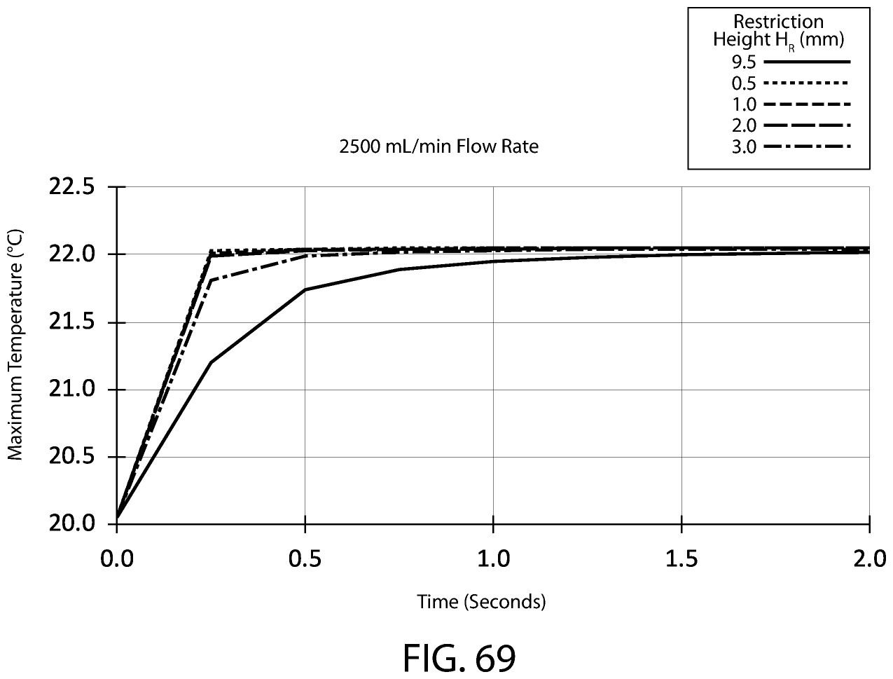

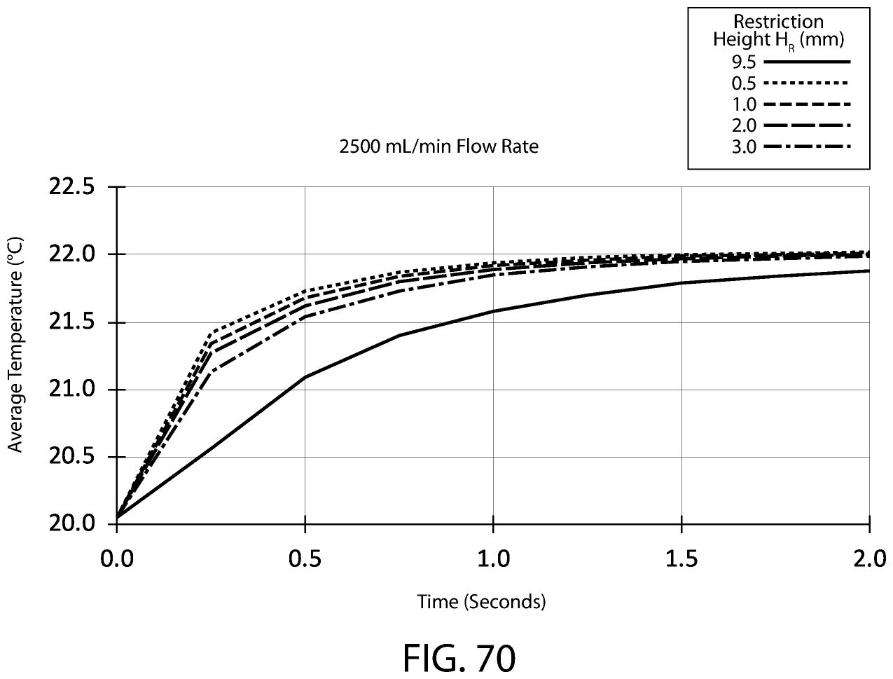

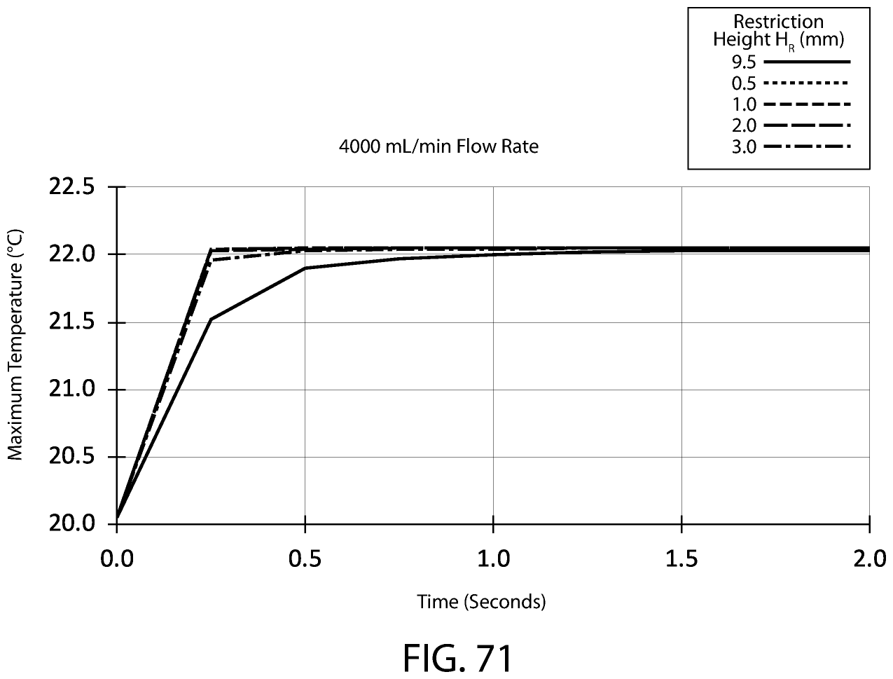

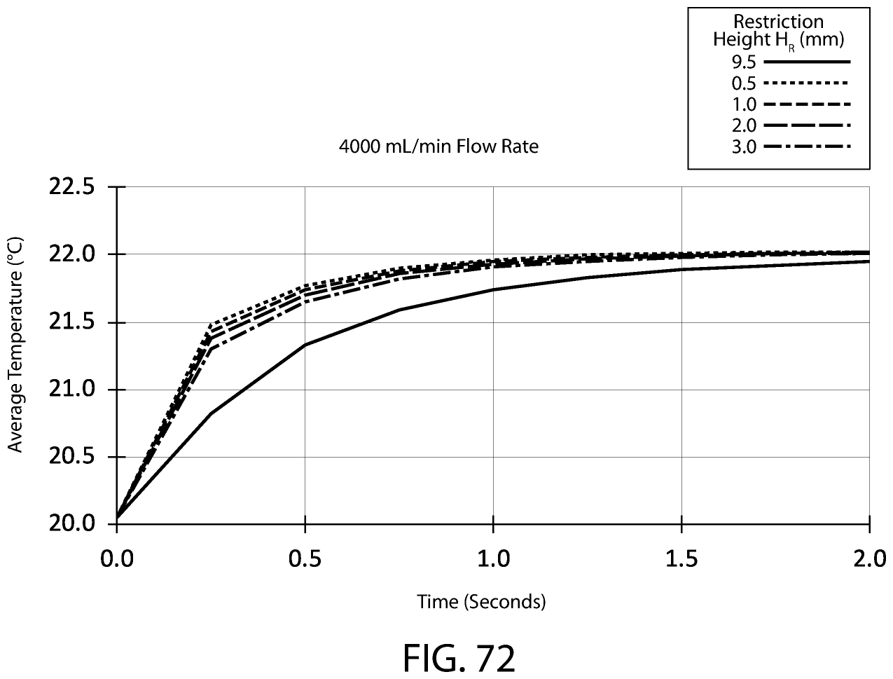

FIGS. 65-72 show a series of graphs of temperature of the top surface 831 of the sensing element 830 are shown for various restriction heights H_{R} in the flow path and various fluid flow rates. Tables 1 and 2 below show the data which form the basis of FIGS. 65-72. The data was generated using computational fluid dynamics software. The portions are at an initial steady state temperature of 20.05 degrees C. A stepwise increase in temperature of the fluid of 2 degrees C. is applied at a transition time at 0 seconds. The fluid flow rates range from 400 mL/min to 4000 mL/min. The sensing thickness T_{H} is 0.5 mm. The restriction height H_{R} ranges from 0.5 mm to 9.5 mm where the restriction element 842 is omitted. Table 1 shows the maximum temperature of the top surface 831 of the sensing element 830 while Table 2 shows the average temperature of the top surface 831 of the sensing element 830. Measurements are taken at 0.25 second intervals from the transition time at 0 seconds to 2.0 seconds. All calculations are performed using the embodiments illustrated in FIGS. 48-56.

TABLE 1
Maximum Temperature of Top Surface of Sensing Element

| | | | | Maximum Temperature of Top Surface of Sensing Element [° C.] | | | | | | | | |
|---|---|---|---|---|---|---|---|---|---|---|---|---|
| Delta T [° C.] | T_{H} [mm] | Flow [mL/min] | H_{R} [mm] | 0 s | 0.25 s | 0.5 s | 0.75 s | 1 s | 1.25 s | 1.5 s | 1.75 s | 2 s |
| 2 | 0.5 | 400 | 9.5 | 20.05 | 20.06 | 20.44 | 20.77 | 21.04 | 21.23 | 21.39 | 21.50 | 21.59 |
| 2 | 0.5 | 400 | 0.5 | 20.05 | 21.33 | 21.87 | 21.96 | 21.99 | 22.01 | 22.02 | 22.02 | 22.03 |
| 2 | 0.5 | 400 | 1 | 20.05 | 21.14 | 21.77 | 21.90 | 21.95 | 21.98 | 21.99 | 22.00 | 22.01 |
| 2 | 0.5 | 400 | 2 | 20.05 | 21.06 | 21.71 | 21.87 | 21.92 | 21.95 | 21.97 | 21.99 | 22.00 |
| 2 | 0.5 | 400 | 3 | 20.05 | 20.84 | 21.50 | 21.73 | 21.81 | 21.87 | 21.91 | 21.94 | 21.96 |
| 2 | 0.5 | 1250 | 9.5 | 20.05 | 20.71 | 21.32 | 21.63 | 21.78 | 21.86 | 21.90 | 21.93 | 21.96 |
| 2 | 0.5 | 1250 | 0.5 | 20.05 | 21.96 | 22.03 | 22.04 | 22.04 | 22.04 | 22.04 | 22.04 | 22.05 |
| 2 | 0.5 | 1250 | 1 | 20.05 | 21.90 | 22.01 | 22.03 | 22.04 | 22.04 | 22.04 | 22.04 | 22.04 |
| 2 | 0.5 | 1250 | 2 | 20.05 | 21.84 | 21.99 | 22.02 | 22.03 | 22.03 | 22.04 | 22.04 | 22.04 |
| 2 | 0.5 | 1250 | 3 | 20.05 | 21.52 | 21.87 | 21.95 | 21.99 | 22.00 | 22.02 | 22.02 | 22.03 |
| 2 | 0.5 | 2500 | 9.5 | 20.05 | 21.20 | 21.74 | 21.89 | 21.95 | 21.98 | 22.00 | 22.01 | 22.02 |
| 2 | 0.5 | 2500 | 0.5 | 20.05 | 22.03 | 22.04 | 22.05 | 22.05 | 22.05 | 22.05 | 22.05 | 22.05 |
| 2 | 0.5 | 2500 | 1 | 20.05 | 22.01 | 22.04 | 22.04 | 22.05 | 22.05 | 22.05 | 22.05 | 22.05 |
| 2 | 0.5 | 2500 | 2 | 20.05 | 21.99 | 22.03 | 22.04 | 22.04 | 22.05 | 22.05 | 22.05 | 22.05 |
| 2 | 0.5 | 2500 | 3 | 20.05 | 21.81 | 21.99 | 22.02 | 22.03 | 22.04 | 22.04 | 22.04 | 22.04 |
| 2 | 0.5 | 4000 | 9.5 | 20.05 | 21.52 | 21.90 | 21.97 | 22.00 | 22.02 | 22.03 | 22.03 | 22.03 |
| 2 | 0.5 | 4000 | 0.5 | 20.05 | 22.04 | 22.05 | 22.05 | 22.05 | 22.05 | 22.05 | 22.05 | 22.05 |
| 2 | 0.5 | 4000 | 1 | 20.05 | 22.04 | 22.05 | 22.05 | 22.05 | 22.05 | 22.05 | 22.05 | 22.05 |
| 2 | 0.5 | 4000 | 2 | 20.05 | 22.03 | 22.04 | 22.05 | 22.05 | 22.05 | 22.05 | 22.05 | 22.05 |
| 2 | 0.5 | 4000 | 3 | 20.05 | 21.96 | 22.03 | 22.04 | 22.04 | 22.05 | 22.05 | 22.05 | 22.05 |

TABLE 2
Average Temperature of Top Surface of Sensing Element

| | | | | Average Temperature of Top Surface of Sensing Element [° C.] | | | | | | | | |
|---|---|---|---|---|---|---|---|---|---|---|---|---|
| Delta T [° C.] | T_{H} [mm] | Flow [mL/min] | H_{R} [mm] | 0 s | 0.25 s | 0.5 s | 0.75 s | 1 s | 1.25 s | 1.5 s | 1.75 s | 2 s |
| 2 | 0.5 | 400 | 9.5 | 20.05 | 20.05 | 20.15 | 20.34 | 20.54 | 20.73 | 20.90 | 21.05 | 21.18 |
| 2 | 0.5 | 400 | 0.5 | 20.05 | 20.61 | 21.21 | 21.49 | 21.67 | 21.77 | 21.84 | 21.89 | 21.92 |
| 2 | 0.5 | 400 | 1 | 20.05 | 20.49 | 21.06 | 21.37 | 21.56 | 21.68 | 21.77 | 21.83 | 21.87 |
| 2 | 0.5 | 400 | 2 | 20.05 | 20.45 | 21.00 | 21.31 | 21.50 | 21.63 | 21.72 | 21.79 | 21.84 |
| 2 | 0.5 | 400 | 3 | 20.05 | 20.34 | 20.85 | 21.16 | 21.36 | 21.51 | 21.62 | 21.70 | 21.76 |
| 2 | 0.5 | 1250 | 9.5 | 20.05 | 20.27 | 20.70 | 21.04 | 21.27 | 21.44 | 21.57 | 21.66 | 21.73 |
| 2 | 0.5 | 1250 | 0.5 | 20.05 | 21.24 | 21.61 | 21.80 | 21.89 | 21.94 | 21.97 | 21.99 | 22.00 |
| 2 | 0.5 | 1250 | 1 | 20.05 | 21.12 | 21.53 | 21.73 | 21.84 | 21.91 | 21.95 | 21.97 | 21.98 |
| 2 | 0.5 | 1250 | 2 | 20.05 | 21.04 | 21.46 | 21.67 | 21.80 | 21.87 | 21.92 | 21.95 | 21.97 |
| 2 | 0.5 | 1250 | 3 | 20.05 | 20.86 | 21.31 | 21.55 | 21.70 | 21.80 | 21.86 | 21.90 | 21.93 |
| 2 | 0.5 | 2500 | 9.5 | 20.05 | 20.56 | 21.09 | 21.40 | 21.58 | 21.70 | 21.79 | 21.84 | 21.88 |
| 2 | 0.5 | 2500 | 0.5 | 20.05 | 21.42 | 21.73 | 21.87 | 21.94 | 21.98 | 22.00 | 22.01 | 22.02 |
| 2 | 0.5 | 2500 | 1 | 20.05 | 21.34 | 21.68 | 21.84 | 21.92 | 21.96 | 21.99 | 22.00 | 22.01 |
| 2 | 0.5 | 2500 | 2 | 20.05 | 21.27 | 21.62 | 21.80 | 21.89 | 21.94 | 21.97 | 21.99 | 22.00 |
| 2 | 0.5 | 2500 | 3 | 20.05 | 21.13 | 21.54 | 21.73 | 21.85 | 21.91 | 21.95 | 21.97 | 21.99 |
| 2 | 0.5 | 4000 | 9.5 | 20.05 | 20.82 | 21.33 | 21.59 | 21.74 | 21.83 | 21.89 | 21.92 | 21.95 |
| 2 | 0.5 | 4000 | 0.5 | 20.05 | 21.48 | 21.77 | 21.90 | 21.96 | 22.00 | 22.01 | 22.02 | 22.02 |
| 2 | 0.5 | 4000 | 1 | 20.05 | 21.43 | 21.74 | 21.88 | 21.95 | 21.98 | 22.00 | 22.01 | 22.02 |
| 2 | 0.5 | 4000 | 2 | 20.05 | 21.38 | 21.70 | 21.86 | 21.93 | 21.97 | 21.99 | 22.01 | 22.01 |
| 2 | 0.5 | 4000 | 3 | 20.05 | 21.30 | 21.65 | 21.82 | 21.91 | 21.95 | 21.98 | 22.00 | 22.01 |

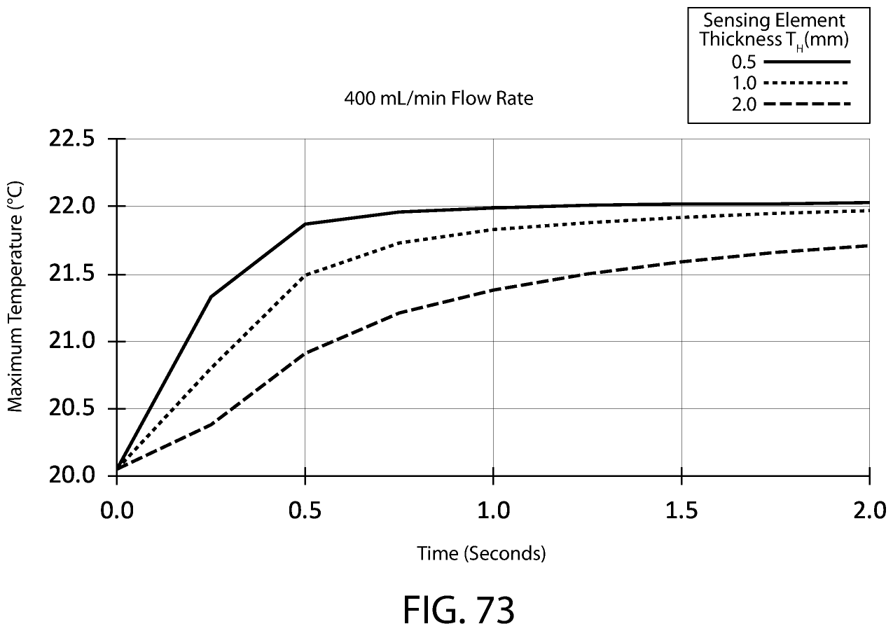

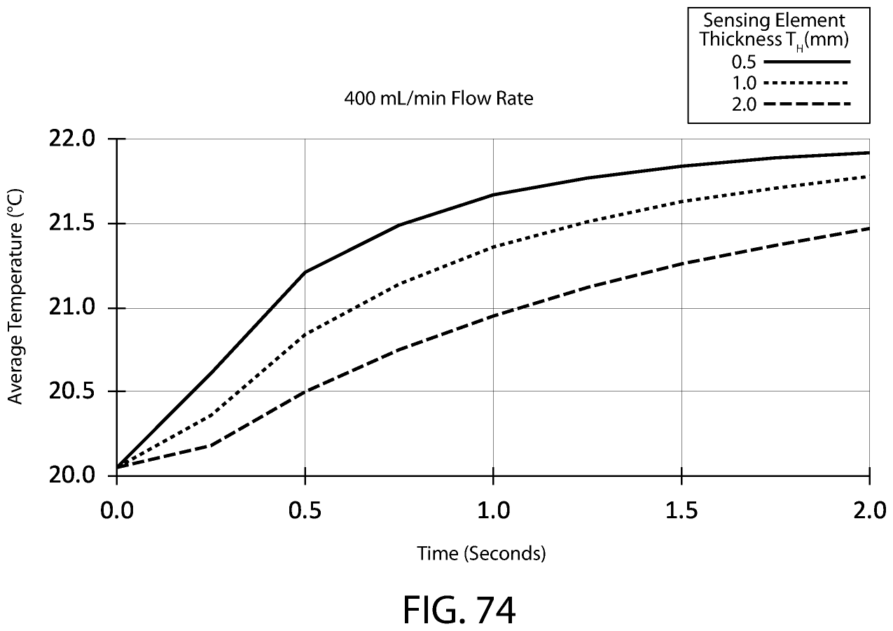

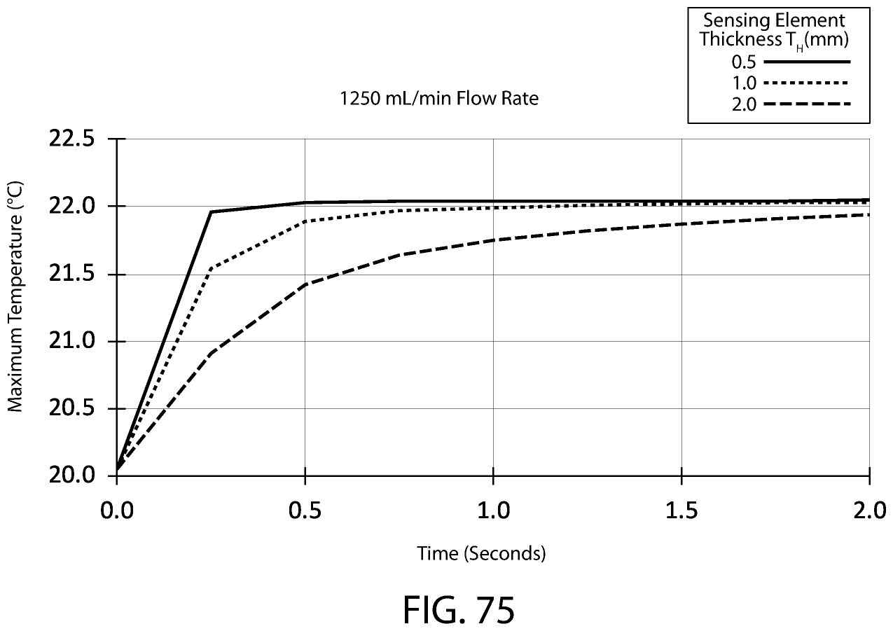

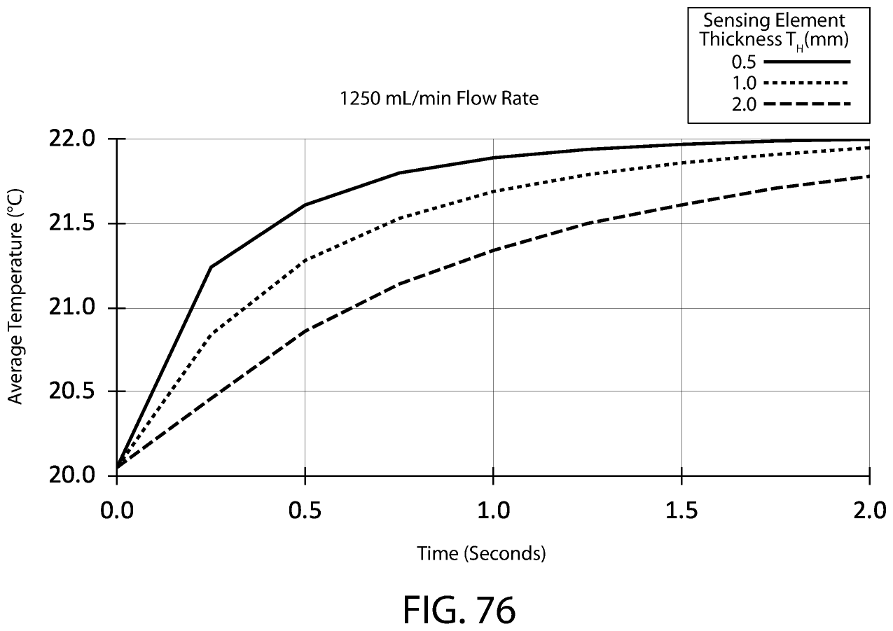

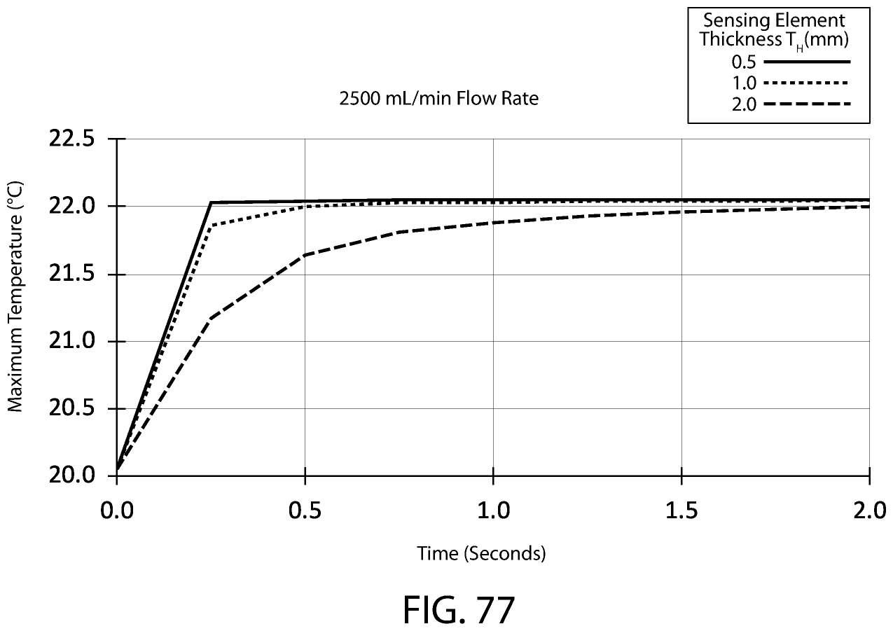

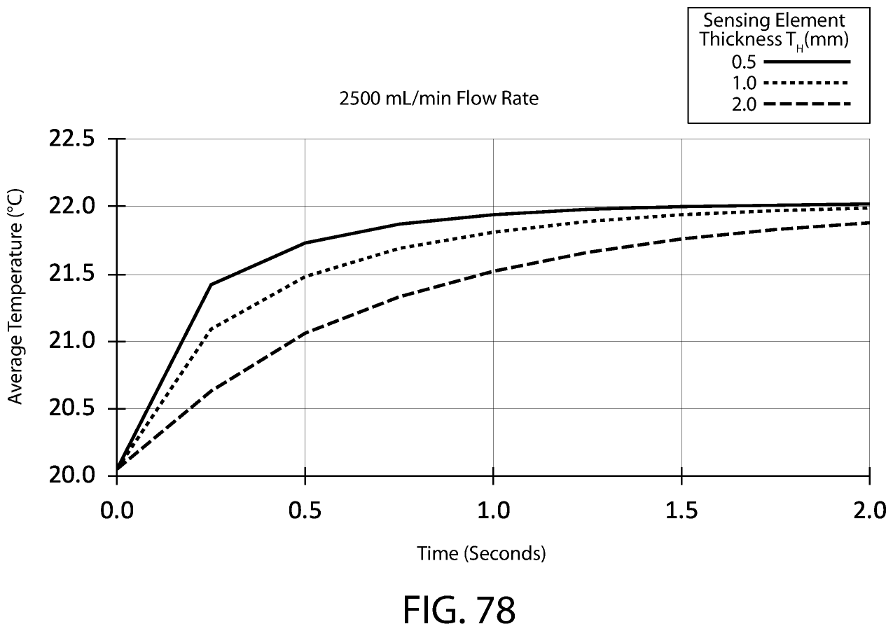

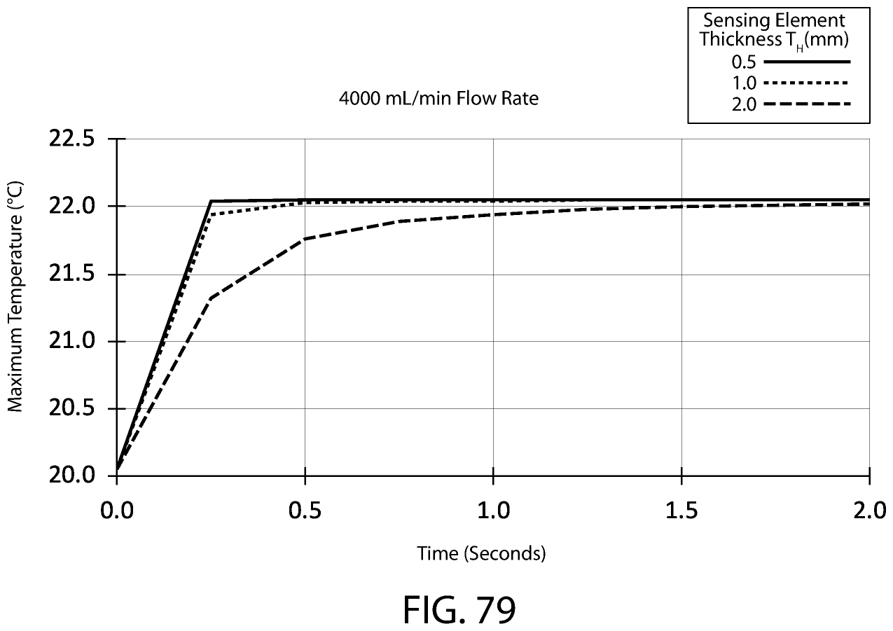

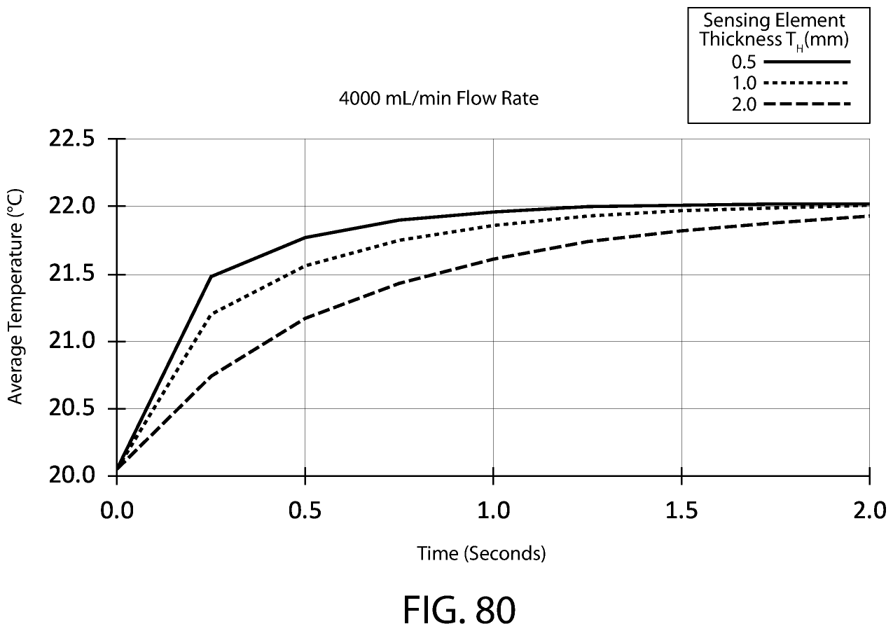

Turning to FIGS. 73-80, a series of graphs of temperature of the top surface 831 of the sensing element 830 are shown for a restriction height H_{R} of 0.5 mm and various fluid flow rates. Tables 3 and 4 below show the data which form the basis of FIGS. 73-80. The data was generated using computational fluid dynamics software. The portions are at an initial steady state temperature of 20.05 degrees C. A stepwise increase in temperature of the fluid of 2 degrees C. is applied at a transition time indicated as 0 seconds. The fluid flow rates range from 400 mL/min to 4000 mL/min. The sensing thickness T_{H} ranges from 0.5 mm to 2.0 mm. Table 3 shows the maximum temperature of the top surface 831 of the sensing element 830 while Table 4 shows the average temperature of the top surface 831 of the sensing element 830. Measurements are taken at 0.25 second intervals from the transition time at 0 seconds to 2.0 seconds. All calculations are performed using the embodiments illustrated in FIGS. 48-56.

TABLE 3
Maximum Temperature of Top Surface of Sensing Element

| | | | | Maximum Temperature of Top Surface of Sensing Element [° C.] | | | | | | | | |
|---|---|---|---|---|---|---|---|---|---|---|---|---|
| Delta T [° C.] | T_{H} [mm] | Flow [mL/min] | H_{R} [mm] | 0 s | 0.25 s | 0.5 s | 0.75 s | 1 s | 1.25 s | 1.5 s | 1.75 s | 2 s |
| 2 | 0.5 | 400 | 0.5 | 20.05 | 21.33 | 21.87 | 21.96 | 21.99 | 22.01 | 22.02 | 22.02 | 22.03 |
| 2 | 1 | 400 | 0.5 | 20.05 | 20.80 | 21.49 | 21.73 | 21.83 | 21.88 | 21.92 | 21.95 | 21.97 |
| 2 | 2 | 400 | 0.5 | 20.05 | 20.38 | 20.91 | 21.21 | 21.38 | 21.50 | 21.59 | 21.66 | 21.71 |
| 2 | 0.5 | 1250 | 0.5 | 20.05 | 21.96 | 22.03 | 22.04 | 22.04 | 22.04 | 22.04 | 22.04 | 22.05 |
| 2 | 1 | 1250 | 0.5 | 20.05 | 21.54 | 21.89 | 21.97 | 21.99 | 22.01 | 22.02 | 22.03 | 22.03 |
| 2 | 2 | 1250 | 0.5 | 20.05 | 20.91 | 21.42 | 21.64 | 21.75 | 21.82 | 21.87 | 21.91 | 21.94 |
| 2 | 0.5 | 2500 | 0.5 | 20.05 | 22.03 | 22.04 | 22.05 | 22.05 | 22.05 | 22.05 | 22.05 | 22.05 |
| 2 | 1 | 2500 | 0.5 | 20.05 | 21.86 | 22.00 | 22.03 | 22.03 | 22.04 | 22.04 | 22.04 | 22.05 |
| 2 | 2 | 2500 | 0.5 | 20.05 | 21.17 | 21.64 | 21.81 | 21.88 | 21.93 | 21.96 | 21.98 | 22.00 |
| 2 | 0.5 | 4000 | 0.5 | 20.05 | 22.04 | 22.05 | 22.05 | 22.05 | 22.05 | 22.05 | 22.05 | 22.05 |
| 2 | 1 | 4000 | 0.5 | 20.05 | 21.94 | 22.03 | 22.04 | 22.04 | 22.05 | 22.05 | 22.05 | 22.05 |
| 2 | 2 | 4000 | 0.5 | 20.05 | 21.32 | 21.76 | 21.89 | 21.94 | 21.98 | 22.00 | 22.01 | 22.02 |

TABLE 4
Average Temperature of Top Surface of Sensing Element

| | | | | Average Temperature of Top Surface of Sensing Element [° C.] | | | | | | | | |
|---|---|---|---|---|---|---|---|---|---|---|---|---|
| Delta T [° C.] | T_{H} [mm] | Flow [mL/min] | H_{R} [mm] | 0 s | 0.25 s | 0.5 s | 0.75 s | 1 s | 1.25 s | 1.5 s | 1.75 s | 2 s |
| 2 | 0.5 | 400 | 0.5 | 20.05 | 20.61 | 21.21 | 21.49 | 21.67 | 21.77 | 21.84 | 21.89 | 21.92 |
| 2 | 1 | 400 | 0.5 | 20.05 | 20.36 | 20.84 | 21.14 | 21.36 | 21.51 | 21.63 | 21.71 | 21.78 |
| 2 | 2 | 400 | 0.5 | 20.05 | 20.18 | 20.50 | 20.75 | 20.95 | 21.12 | 21.26 | 21.37 | 21.47 |
| 2 | 0.5 | 1250 | 0.5 | 20.05 | 21.24 | 21.61 | 21.80 | 21.89 | 21.94 | 21.97 | 21.99 | 22.00 |
| 2 | 1 | 1250 | 0.5 | 20.05 | 20.84 | 21.28 | 21.53 | 21.69 | 21.79 | 21.86 | 21.91 | 21.95 |
| 2 | 2 | 1250 | 0.5 | 20.05 | 20.46 | 20.86 | 21.14 | 21.34 | 21.50 | 21.61 | 21.71 | 21.78 |
| 2 | 0.5 | 2500 | 0.5 | 20.05 | 21.42 | 21.73 | 21.87 | 21.94 | 21.98 | 22.00 | 22.01 | 22.02 |
| 2 | 1 | 2500 | 0.5 | 20.05 | 21.09 | 21.48 | 21.69 | 21.81 | 21.89 | 21.94 | 21.97 | 21.99 |
| 2 | 2 | 2500 | 0.5 | 20.05 | 20.63 | 21.06 | 21.33 | 21.52 | 21.66 | 21.76 | 21.83 | 21.88 |
| 2 | 0.5 | 4000 | 0.5 | 20.05 | 21.48 | 21.77 | 21.90 | 21.96 | 22.00 | 22.01 | 22.02 | 22.02 |
| 2 | 1 | 4000 | 0.5 | 20.05 | 21.20 | 21.56 | 21.75 | 21.86 | 21.93 | 21.97 | 21.99 | 22.01 |
| 2 | 2 | 4000 | 0.5 | 20.05 | 20.74 | 21.17 | 21.43 | 21.61 | 21.74 | 21.82 | 21.88 | 21.93 |

A restriction ratio is defined by dividing the restriction height H_{R} by the restriction width W_{R}. In one example, the restriction height H_{R} is 3 mm and the restriction width W_{R} is 12 mm, resulting in a restriction ratio of 0.25. In another example, the restriction height H_{R} is 2 mm and the restriction width W_{R} is 12 mm, resulting in a restriction ratio of 0.167. In yet another example, the restriction height H_{R} is 1 mm and the restriction width W_{R} is 12 mm, resulting in a restriction ratio of 0.083. In another example, the restriction height H_{R} is 0.5 mm and the restriction width W_{R} is 12 mm, resulting in a restriction ratio of 0.042. As the restriction ratio decreases, the response times for the maximum and average temperatures of the top surface 831 of the sensing element 830 decrease, resulting in improved sensing performance.

A transition ratio is defined by dividing the restriction height H_{R} by the unrestricted height H_{U}. In one example, the restriction height H_{R} is 3 mm and the unrestricted height H_{U} is 9.5 mm, resulting in a transition ratio of 0.316. In another example, the restriction height H_{R} is 2 mm and the unrestricted height H_{U} is 9.5 mm, resulting in a transition ratio of 0.211. In yet another example, the restriction height H_{R} is 1 mm and the unrestricted height H_{U} is 9.5 mm, resulting in a transition ratio of 0.105. In another example, the restriction height H_{R} is 0.5 mm and the unrestricted height H_{U} is 9.5 mm, resulting in a transition ratio of 0.053. As the transition ratio increases, the response times for the maximum and average temperatures of the top surface 831 of the sensing element 830 decrease, resulting in improved sensing performance.

An exemplary claim set is provided below to further describe the invention.

Exemplary claim 1: A system for processing articles, the system comprising: a fluid supply configured to supply a process fluid; a process chamber configured to process articles; a fluid delivery module, the fluid delivery module comprising: an inlet fluidly coupled to the fluid supply; an outlet fluidly coupled to the process chamber; a flow passage extending from the inlet to the outlet; a fluid flow component, the fluid flow component comprising: a component base; an inlet port formed in the component base; an outlet port formed in the component base; a flow path extending from the inlet port to the outlet port, the flow path forming a portion of the flow passage; a sensing port in fluid communication with the flow path and located between the inlet port and the outlet port; a sensing element sealing the sensing port; and a sensor isolated from the process fluid by the sensing element, the sensor configured to detect a property of the process fluid within the flow path.

Exemplary claim 2: The system of exemplary claim 1 wherein the sensing element comprises sapphire.

Exemplary claim 3: The system of exemplary claim 1 or exemplary claim 2 wherein the sensor is a temperature sensor.

Exemplary claim 4: The system of exemplary claim 3 wherein the sensor is a non-contact temperature sensor.

Exemplary claim 5: The system of any one of exemplary claims 1 to 4 wherein the sensor is in direct contact with a spacer, the spacer being in direct contact with the sensing element.

Exemplary claim 6: The system of exemplary claim 5 wherein the spacer has a conical inner surface.

Exemplary claim 7: The system of exemplary claim 5 or exemplary claim 6 wherein the spacer has a plurality of notches in a bottom surface of the spacer, the bottom surface being in contact with the sensing element.

Exemplary claim 8: The system of any one of exemplary claims 5 to 7 wherein the spacer is compressed between the sensing element and a sensor housing, the sensor and the spacer located within a cavity in the sensor housing.

Exemplary claim 9: The system of any one of exemplary claims 1 to 8 wherein the sensing port comprises a groove configured to accept an O-ring.

Exemplary claim 10: The system of any one of exemplary claims 1 to 9 wherein the sensing port comprises a first sealing rib.

Exemplary claim 11: The system of exemplary claim 10 wherein the sensing port comprises a second sealing rib concentric with the first sealing rib.

Exemplary claim 12: The system of exemplary claim 1 wherein the sensing element comprises a polymer.

Exemplary claim 13: The system of exemplary claim 1 or exemplary claim 12 wherein the sensing port comprises a groove configured to accept an annular ring of the sensing element.

Exemplary claim 14: The system of exemplary claim 1 or any one of exemplary claim 12 or 13 wherein the sensor is a pressure sensor.

Exemplary claim 15: The system of exemplary claim 1 or any one of exemplary claims 12 to 14 wherein the sensor is in direct contact with the sensing element.

Exemplary claim 16: The system of exemplary claim 15 wherein the sensor is compressed between the sensing element and a sensor housing, the sensor located within a cavity in the sensor housing.

Exemplary claim 17: The system of any one of exemplary claims 1 to 16 wherein the fluid flow component comprises a sensor housing coupled to the component base, the sensor housing enclosing the sensor.

Exemplary claim 18: The system of exemplary claim 17 further comprising a second fluid flow component, the second fluid flow component comprising: a component base; an inlet port formed in the component base; an outlet formed in the component base; a flow path extending from the inlet port to the outlet port, the flow path forming a portion of the flow passage; a sensing port in fluid communication with the flow path and located between the inlet port and the outlet port; a sensing element sealing the sensing port; a sensor isolated from the process fluid by the sensing element, the sensor configured to detect a second property of the process fluid within the flow path; and a sensor housing coupled to the component base and enclosing the sensor; wherein the property detected by the sensor of the fluid flow component is different from the second property detected by the sensor of the second fluid flow component; and wherein the sensor housing of the fluid flow component is identical to the sensor housing of the second fluid flow component.

Exemplary claim 19: A system for processing articles, the system comprising: a fluid supply configured to supply at least one process fluid; a process chamber configured to process articles; a fluid delivery module, the fluid delivery module comprising: an inlet fluidly coupled to the fluid supply; an outlet fluidly coupled to the process chamber; a flow passage extending from the inlet to the outlet; a first fluid flow component, the first fluid flow component comprising: a first component base; a first inlet port formed in the first component base; a first outlet port formed in the first component base; a first flow path extending from the first inlet port to the first outlet port, the first flow path forming a portion of the flow passage; a first sensor configured to detect a first property of the at least one process fluid within the first flow path; a first sensor housing coupled to the first component base and enclosing the first sensor; a second fluid flow component, the second fluid flow component comprising: a second component base; a second inlet port formed in the second component base; a second outlet port formed in the second component base; a second flow path extending from the second inlet port to the second outlet port, the second flow path forming a portion of the flow passage; a second sensor configured to detect a second property of the at least one process fluid within the second flow path; a second sensor housing coupled to the second component base and enclosing the second sensor; wherein the first and second sensors are different; and wherein the first and second sensor housings are identical.

Exemplary claim 20: The system of exemplary claim 19 wherein the first and second properties are different.

Exemplary claim 21: The system of exemplary claim 19 or exemplary claim 20 wherein the first and second sensor housings each comprise a cavity, the first sensor enclosed by the first sensor housing and the second sensor housing enclosing the second sensor.

Exemplary claim 22: The system of any one of exemplary claims 19 to 21 wherein the first sensor is a temperature sensor.

Exemplary claim 23: The system of any one of exemplary claims 19 to 22 wherein the first fluid flow component further comprises a first spacer, the first sensor housing in direct contact with the first sensor and the first sensor in direct contact with the first spacer.

Exemplary claim 24: The system of exemplary claim 23 further comprising a first sensing element and a first sensing port, the first sensing element sealing the first sensing port and the spacer in direct contact with the first spacer.

Exemplary claim 25: The system of any one of exemplary claims 19 to 24 wherein the second sensor is a pressure sensor.

Exemplary claim 26: The system of any one of exemplary claims 19 to 25 wherein the second fluid flow component further comprises a second sensing element and a second sensing port, the second sensor in direct contact with the second sensor housing and the second sensing element and the second sensing element sealing the second sensing port.

Exemplary claim 27: A fluid flow component, the fluid flow component comprising: a component base; an inlet port formed in the component base; an outlet port formed in the component base; a flow path extending from the inlet port to the outlet port; a sensing port in fluid communication with the flow path and located between the inlet port and the outlet port; a sensing element sealing the sensing port; and a sensor isolated from the process fluid by the sensing element, the sensor configured to detect a property of the process fluid within the flow path.

Exemplary claim 28: The fluid flow component of exemplary claim 27 wherein the sensing element comprises sapphire.

Exemplary claim 29: The fluid flow component of exemplary claim 27 or exemplary claim 28 wherein the sensor is a temperature sensor.

Exemplary claim 30: The fluid flow component of exemplary claim 29 wherein the sensor is a non-contact temperature sensor.

Exemplary claim 31: The fluid flow component of any one of exemplary claims 27 to 30 wherein the sensor is in direct contact with a spacer, the spacer being in direct contact with the sensing element.

Exemplary claim 32: The fluid flow component of exemplary claim 31 wherein the spacer has a conical inner surface.

Exemplary claim 33: The fluid flow component of exemplary claim 31 or exemplary claim 32 wherein the spacer has a plurality of notches in a bottom surface of the spacer, the bottom surface being in contact with the sensing element.

Exemplary claim 34: The fluid flow component of any one of exemplary claims 31 to 33 wherein the spacer is compressed between the sensing element and a sensor housing, the sensor and the spacer located within a cavity in the sensor housing.

Exemplary claim 35: The fluid flow component of any one of exemplary claims 27 to 34 wherein the sensing port comprises a groove configured to accept an O-ring.

Exemplary claim 36: The fluid flow component of any one of exemplary claims 27 to 35 wherein the sensing port comprises a first sealing rib.

Exemplary claim 37: The fluid flow component of exemplary claim 36 wherein the sensing port comprises a second sealing rib concentric with the first sealing rib.

Exemplary claim 38: The fluid flow component of exemplary claim 27 wherein the sensing element comprises a polymer.

Exemplary claim 39: The fluid flow component of exemplary claim 27 or exemplary claim 38 wherein the sensing port comprises a groove configured to accept an annular ring of the sensing element.

Exemplary claim 40: The fluid flow component of exemplary claim 27 or any one of exemplary claim 38 or 39 wherein the sensor is a pressure sensor.

Exemplary claim 41: The fluid flow component of exemplary claim 27 or any one of exemplary claims 38 to 40 wherein the sensor is in direct contact with the sensing element.

Exemplary claim 42: The fluid flow component of exemplary claim 41 wherein the sensor is compressed between the sensing element and a sensor housing, the sensor located within a cavity in the sensor housing.

Exemplary claim 43: The fluid flow component of any one of exemplary claims 27 to 42 wherein the fluid flow component comprises a sensor housing coupled to the component base, the sensor housing enclosing the sensor.

Exemplary claim 44: A method of manufacturing articles, the method comprising: a) providing a fluid delivery module, the fluid delivery module comprising an inlet, an outlet, a flow passage extending from the inlet to the outlet, and a fluid flow component comprising a flow path extending from an inlet port to an outlet port, the flow path forming a portion of the flow passage; b) supplying a process fluid to the inlet of the fluid delivery module; c) flowing the process fluid through the flow passage, the process fluid flowing through the flow path of the fluid flow component to the outlet of the fluid delivery module, the outlet of the fluid delivery module fluidly coupled to an outlet manifold; d) measuring a property of the process fluid via a sensing port in fluid communication with the flow path of the fluid flow component between the inlet port and the outlet port, the sensing port sealed by a sensing element, and a sensor operably coupled to the sensing element; e) delivering the process fluid from the outlet of the fluid delivery module to a processing chamber via the outlet manifold, the outlet manifold fluidly coupled to the processing chamber; and f) performing a process on an article within the processing chamber.

Exemplary claim 45: The method of exemplary claim 44 wherein the sensing element comprises sapphire.

Exemplary claim 46: The method of exemplary claim 44 or exemplary claim 45 wherein the sensor is a temperature sensor.

Exemplary claim 47: The method of exemplary claim 46 wherein the sensor is a non-contact temperature sensor.

Exemplary claim 48: The method of any one of exemplary claims 44 to 47 wherein the sensor is in direct contact with a spacer, the spacer being in direct contact with the sensing element.

Exemplary claim 49: The method of exemplary claim 48 wherein the spacer has a conical inner surface.

Exemplary claim 50: The method of exemplary claim 48 or exemplary claim 49 wherein the spacer has a plurality of notches in a bottom surface of the spacer, the bottom surface being in contact with the sensing element.

Exemplary claim 51: The method of any one of exemplary claims 48 to 50 wherein the spacer is compressed between the sensing element and a sensor housing, the sensor and the spacer located within a cavity in the sensor housing.

Exemplary claim 52: The method of any one of exemplary claims 44 to 51 wherein the sensing port comprises a groove configured to accept an O-ring.

Exemplary claim 53: The method of any one of exemplary claims 44 to 52 wherein the sensing port comprises a first sealing rib.

Exemplary claim 54: The method of exemplary claim 53 wherein the sensing port comprises a second sealing rib concentric with the first sealing rib.

Exemplary claim 55: The method of exemplary claim 44 wherein the sensing element comprises a polymer.

Exemplary claim 56: The method of exemplary claim 44 or exemplary claim 55 wherein the sensing port comprises a groove configured to accept an annular ring of the sensing element.

Exemplary claim 57: The method of exemplary claim 44 or any one of exemplary claim 55 or 56 wherein the sensor is a pressure sensor.

Exemplary claim 58: The method of exemplary claim 44 or any one of exemplary claims 55 to 57 wherein the sensor is in direct contact with the sensing element.

Exemplary claim 59: The method of exemplary claim 58 wherein the sensor is compressed between the sensing element and a sensor housing, the sensor located within a cavity in the sensor housing.

Exemplary claim 60: A fluid flow component, the fluid flow component comprising: a component base; an inlet port formed in the component base; an outlet port formed in the component base; a flow path extending from the inlet port to the outlet port; and a sensing element having a bottom side and a top side, the bottom side in contact with a process fluid flowing through the flow path, the flow path having a restriction height and a restriction width at a restriction plane intersecting the sensing element; wherein a restriction ratio between the restriction height and the restriction width is 0.25 or less.

Exemplary claim 61: The fluid flow component of exemplary claim 60 wherein the restriction ratio is 0.167 or less.

Exemplary claim 62: The fluid flow component of exemplary claim 61 wherein the restriction ratio is 0.083 or less.

Exemplary claim 63: The fluid flow component of any one of exemplary claims 60 to 62 further comprising a restriction element, the restriction plane intersecting the restriction element.

Exemplary claim 64: The fluid flow component of any one of exemplary claims 60 to 63 further comprising a restriction element, the restriction height measured between the bottom side of the sensing element and the restriction element.

Exemplary claim 65: The fluid flow component of exemplary claim 64 further comprising an actuator, the actuator operably coupled to the restriction element.

Exemplary claim 66: The fluid flow component of exemplary claim 65 wherein the actuator is configured to vary the restriction height.

Exemplary claim 67: The fluid flow component of any one of exemplary claims 60 to 66 wherein the flow path has an unrestricted height extending from the sensing element to a floor of a sensing port, the unrestricted height being greater than the restriction height.

Exemplary claim 68: The fluid flow component of exemplary claim 67 wherein a transition ratio between the restriction height and the unrestricted height is 0.316 or less.

Exemplary claim 69: The fluid flow component of exemplary claim 68 wherein the transition ratio is 0.211 or less.

Exemplary claim 70: The fluid flow component of exemplary claim 69 wherein the transition ratio is 0.105 or less.

Exemplary claim 71: The fluid flow component of any one of exemplary claims 60 to 70 wherein the sensing element has a thickness of 3 mm or less.

Exemplary claim 72: The fluid flow component of any one of exemplary claims 60 to 71 wherein the sensing element has a thickness of 1 mm or less.

Exemplary claim 73: The fluid flow component of any one of exemplary claims 60 to 72 wherein the sensing element has a thickness that is less than the restriction height.

Exemplary claim 74: The fluid flow component of any one of exemplary claims 60 to 73 wherein, when the process fluid is liquid water at a flow rate of 400 mL per minute and a steady state temperature of 20.05 degrees C., a stepwise increase in temperature of 2 degrees C. applied to the process fluid at a transition time results in the top side of the sensing element having a maximum temperature of 21.5 degrees C. or greater at 0.5 seconds from the transition time.

Exemplary claim 75: The fluid flow component of any one of exemplary claims 60 to 74 wherein, when the process fluid is liquid water at a flow rate of 400 mL per minute and a steady state temperature of 20.05 degrees C., a stepwise increase in temperature of 2 degrees C. applied to the process fluid at a transition time results in the top side of the sensing element having an average temperature of 20.85 degrees C. or greater at 0.5 seconds from the transition time.

Exemplary claim 76: The fluid flow component of any one of exemplary claims 60 to 75 wherein, when the process fluid is liquid water at a flow rate of 1250 mL per minute and a steady state temperature of 20.05 degrees C., a stepwise increase in temperature of 2 degrees C. applied to the process fluid at a transition time results in the top side of the sensing element having a maximum temperature of 21.52 degrees C. or greater at 0.5 seconds from the transition time.

Exemplary claim 77: The fluid flow component of any one of exemplary claims 60 to 76 wherein, when the process fluid is liquid water at a flow rate of 1250 mL per minute and a steady state temperature of 20.05 degrees C., a stepwise increase in temperature of 2 degrees C. applied to the process fluid at a transition time results in the top side of the sensing element having an average temperature of 20.86 degrees C. or greater at 0.5 seconds from the transition time.

Exemplary claim 78: The fluid flow component of any one of exemplary claims 74 to 77 wherein the sensing element has a thickness of 0.5 mm.

Exemplary claim 79: A fluid flow component, the fluid flow component comprising: a component base; an inlet port formed in the component base; an outlet port formed in the component base; a flow path extending from the inlet port to the outlet port; and a sensing element having a bottom side and a top side, the bottom side in contact with a process fluid flowing through the flow path, the flow path having a restriction height at a restriction plane intersecting the sensing element and an unrestricted height extending from the sensing element to a floor of a sensing port; wherein a transition ratio between the restriction height and the unrestricted height is 0.316 or less.

Exemplary claim 80: The fluid flow component of exemplary claim 79 wherein the transition ratio is 0.211 or less.

Exemplary claim 81: The fluid flow component of exemplary claim 79 or exemplary claim 80 wherein the transition ratio is 0.105 or less.

Exemplary claim 82: The fluid flow component of any one of exemplary claims 79 to 81 wherein the flow path has a restriction width measured along the restriction plane.

Exemplary claim 83: The fluid flow component of exemplary claim 82 wherein a restriction ratio between the restriction height and the restriction width is 0.25 or less.

Exemplary claim 84: The fluid flow component of exemplary claim 83 wherein the restriction ratio is 0.167 or less.

Exemplary claim 85: The fluid flow component of exemplary claim 83 or exemplary claim 84 wherein the restriction ratio is 0.083 or less.

Exemplary claim 86: The fluid flow component of any one of exemplary claims 79 to 85 further comprising a restriction element, the restriction plane intersecting the restriction element.

Exemplary claim 87: The fluid flow component of any one of exemplary claims 79 to 86 further comprising a restriction element, the restriction height measured between the bottom side of the sensing element and the restriction element.

Exemplary claim 88: The fluid flow component of exemplary claims 79 to 87 further comprising a restriction element and an actuator, the actuator operably coupled to the restriction element.

Exemplary claim 89: The fluid flow component of exemplary claim 88 wherein the actuator is configured to vary the restriction height.

Exemplary claim 90: The fluid flow component of any one of exemplary claims 79 to 89 wherein the unrestricted height is greater than the restriction height.

Exemplary claim 91: The fluid flow component of any one of exemplary claims 79 to 90 wherein the sensing element has a thickness of 3 mm or less.

Exemplary claim 92: The fluid flow component of any one of exemplary claims 79 to 91 wherein the sensing element has a thickness of 1 mm or less.

Exemplary claim 93: The fluid flow component of any one of exemplary claims 79 to 92 wherein the sensing element has a thickness that is less than the restriction height.

Exemplary claim 94: The fluid flow component of any one of exemplary claims 79 to 93 wherein the fluid flow component is configured such that when the process fluid is liquid water at a flow rate of 400 mL per minute and a steady state temperature of 20.05 degrees C., a stepwise increase in temperature of 2 degrees C. applied to the process fluid at a transition time results in the top side of the sensing element having a maximum temperature of 21.5 degrees C. or greater at 0.5 seconds from the transition time.

Exemplary claim 95: The fluid flow component of any one of exemplary claims 79 to 94 wherein the fluid flow component is configured such that when the process fluid is liquid water at a flow rate of 400 mL per minute and a steady state temperature of 20.05 degrees C., a stepwise increase in temperature of 2 degrees C. applied to the process fluid at a transition time results in the top side of the sensing element having an average temperature of 20.85 degrees C. or greater at 0.5 seconds from the transition time.

Exemplary claim 96: The fluid flow component of any one of exemplary claims 79 to 95 wherein the fluid flow component is configured such that when the process fluid is liquid water at a flow rate of 1250 mL per minute and a steady state temperature of 20.05 degrees C., a stepwise increase in temperature of 2 degrees C. applied to the process fluid at a transition time results in the top side of the sensing element having a maximum temperature of 21.52 degrees C. or greater at 0.5 seconds from the transition time.

Exemplary claim 97: The fluid flow component of any one of exemplary claims 79 to 96 wherein the fluid flow component is configured such that when the process fluid is liquid water at a flow rate of 1250 mL per minute and a steady state temperature of 20.05 degrees C., a stepwise increase in temperature of 2 degrees C. applied to the process fluid at a transition time results in the top side of the sensing element having an average temperature of 20.86 degrees C. or greater at 0.5 seconds from the transition time.

Exemplary claim 98: The fluid flow component of any one of exemplary claims 94 to 97 wherein the sensing element has a thickness of 0.5 mm.

Exemplary claim 99: A fluid flow component, the fluid flow component comprising: a component base; an inlet port formed in the component base; an outlet port formed in the component base; a flow path extending from the inlet port to the outlet port; a sensing element having a bottom side and a top side, the bottom side in contact with a process fluid flowing through the flow path; and a restriction element configured to obstruct the flow path, the flow path having a restriction height between the restriction element and the bottom side of the sensing element which is less than an unrestricted height measured from the bottom side of the sensing element to a floor of the flow path.

Exemplary claim 100: The fluid flow component of exemplary claim 99 wherein a transition ratio between the restriction height and the unrestricted height is 0.316 or less.

Exemplary claim 101: The fluid flow component of exemplary claim 100 wherein the transition ratio is 0.211 or less.

Exemplary claim 102: The fluid flow component of exemplary claim 100 or exemplary claim 101 wherein the transition ratio is 0.105 or less.

Exemplary claim 103: The fluid flow component of any one of exemplary claims 99 to 102 further comprising a restriction plane intersecting the restriction element and the sensing element, the restriction height measured along the restriction plane.

Exemplary claim 104: The fluid flow component of exemplary claim 103 wherein the flow path has a restriction width measured along the restriction plane.

Exemplary claim 105: The fluid flow component of exemplary claim 104 wherein a restriction ratio between the restriction height and the restriction width is 0.25 or less.

Exemplary claim 106: The fluid flow component of exemplary claim 105 wherein the restriction ratio is 0.167 or less.

Exemplary claim 107: The fluid flow component of exemplary claim 105 or claim 106 wherein the restriction ratio is 0.083 or less.

Exemplary claim 108: The fluid flow component of any one of exemplary claims 99 to 107 further comprising an actuator, the actuator operably coupled to the restriction element.

Exemplary claim 109: The fluid flow component of exemplary claim 108 wherein the actuator is configured to vary the restriction height.

Exemplary claim 110: The fluid flow component of any one of exemplary claims 99 to 109 wherein the sensing element has a thickness of 3 mm or less.

Exemplary claim 111: The fluid flow component of any one of exemplary claims 99 to 110 wherein the sensing element has a thickness of 1 mm or less.

Exemplary claim 112: The fluid flow component of any one of exemplary claims 99 to 111 wherein the sensing element has a thickness that is less than the restriction height.

Exemplary claim 113: The fluid flow component of any one of exemplary claims 99 to 112 wherein the fluid flow component is configured such that when the process fluid is liquid water at a flow rate of 400 mL per minute and a steady state temperature of 20.05 degrees C., a stepwise increase in temperature of 2 degrees C. applied to the process fluid at a transition time results in the top side of the sensing element having a maximum temperature of 21.5 degrees C. or greater at 0.5 seconds from the transition time.

Exemplary claim 114: The fluid flow component of any one of exemplary claims 99 to 113 wherein the fluid flow component is configured such that when the process fluid is liquid water at a flow rate of 400 mL per minute and a steady state temperature of 20.05 degrees C., a stepwise increase in temperature of 2 degrees C. applied to the process fluid at a transition time results in the top side of the sensing element having an average temperature of 20.85 degrees C. or greater at 0.5 seconds from the transition time.

Exemplary claim 115: The fluid flow component of any one of exemplary claims 99 to 114 wherein the fluid flow component is configured such that when the process fluid is liquid water at a flow rate of 1250 mL per minute and a steady state temperature of 20.05 degrees C., a stepwise increase in temperature of 2 degrees C. applied to the process fluid at a transition time results in the top side of the sensing element having a maximum temperature of 21.52 degrees C. or greater at 0.5 seconds from the transition time.

Exemplary claim 116: The fluid flow component of any one of exemplary claims 99 to 115 wherein the fluid flow component is configured such that when the process fluid is liquid water at a flow rate of 1250 mL per minute and a steady state temperature of 20.05 degrees C., a stepwise increase in temperature of 2 degrees C. applied to the process fluid at a transition time results in the top side of the sensing element having an average temperature of 20.86 degrees C. or greater at 0.5 seconds from the transition time.

Exemplary claim 117: The fluid flow component of any one of exemplary claims 113 to 116 wherein the sensing element has a thickness of 0.5 mm.

While the invention has been described with respect to specific examples including presently preferred modes of carrying out the invention, those skilled in the art will appreciate that there are numerous variations and permutations of the above-described systems and techniques. It is to be understood that other embodiments may be utilized, and structural and functional modifications may be made without departing from the scope of the present invention. Thus, the spirit and scope of the invention should be construed broadly as set forth in the appended claims.

1. A system for processing articles, the system comprising:
a fluid supply configured to supply a process fluid;
a process chamber configured to process articles;
a fluid delivery module, the fluid delivery module comprising:
an inlet fluidly coupled to the fluid supply;
an outlet fluidly coupled to the process chamber;
a flow passage extending from the inlet to the outlet;
a fluid flow component, the fluid flow component comprising:
a component base;
an inlet port formed in the component base;
an outlet port formed in the component base;
a flow path extending from the inlet port to the outlet port, the flow path forming a portion of the flow passage;
a sensing port in fluid communication with the flow path and located between the inlet port and the outlet port;
a sensing element sealing the sensing port; and
a sensor isolated from the process fluid by the sensing element, the sensor configured to detect a property of the process fluid within the flow path.

2. The system of claim 1 wherein the sensing element comprises sapphire.

3. (canceled)

4. The system of claim 1 wherein the sensor is a non-contact temperature sensor.

5. The system of claim 1 wherein the sensor is in direct contact with a spacer, the spacer being in direct contact with the sensing element.

6. (canceled)

7. The system of claim 5 wherein the spacer has a plurality of notches in a bottom surface of the spacer, the bottom surface being in contact with the sensing element.

8. (canceled)

9. The system of claim 1 wherein the sensing port comprises a groove configured to accept an O-ring.

10. The system of claim 1 wherein the sensing port comprises a first sealing rib.

11. (canceled)

12. The system of claim 1 wherein the sensing element comprises a polymer.

13. (canceled)

14. The system of claim 1 wherein the sensor is a pressure sensor.

15. The system of claim 1 wherein the sensor is in direct contact with the sensing element.

16. (canceled)

17. The system of claim 1 wherein the fluid flow component comprises a sensor housing coupled to the component base, the sensor housing enclosing the sensor.

18. The system of claim 17 further comprising a second fluid flow component, the second fluid flow component comprising:
a component base;
an inlet port formed in the component base;
an outlet formed in the component base;
a flow path extending from the inlet port to the outlet port, the flow path forming a portion of the flow passage;
a sensing port in fluid communication with the flow path and located between the inlet port and the outlet port;
a sensing element sealing the sensing port;
a sensor isolated from the process fluid by the sensing element, the sensor configured to detect a second property of the process fluid within the flow path; and
a sensor housing coupled to the component base and enclosing the sensor;
wherein the property detected by the sensor of the fluid flow component is different from the second property detected by the sensor of the second fluid flow component; and
wherein the sensor housing of the fluid flow component is identical to the sensor housing of the second fluid flow component.

19.-26. (canceled)

27. A fluid flow component, the fluid flow component comprising:
a component base;
an inlet port formed in the component base;
an outlet port formed in the component base;
a flow path extending from the inlet port to the outlet port;
a sensing port in fluid communication with the flow path and located between the inlet port and the outlet port;
a sensing element sealing the sensing port; and
a sensor isolated from the process fluid by the sensing element, the sensor configured to detect a property of the process fluid within the flow path.

28.-30. (canceled)

31. The fluid flow component of claim 27 wherein the sensor is in direct contact with a spacer, the spacer being in direct contact with the sensing element.

32. (canceled)

33. (canceled)

34. The fluid flow component of claim 31 wherein the spacer is compressed between the sensing element and a sensor housing, the sensor and the spacer located within a cavity in the sensor housing.

35.-38. (canceled)

39. The fluid flow component of claim 27 wherein the sensing port comprises a groove configured to accept an annular ring of the sensing element.

40.-42. (canceled)

43. The fluid flow component of claim 27 wherein the fluid flow component comprises a sensor housing coupled to the component base, the sensor housing enclosing the sensor.

44.-59. (canceled)

60. A fluid flow component, the fluid flow component comprising:
a component base;
an inlet port formed in the component base;
an outlet port formed in the component base;
a flow path extending from the inlet port to the outlet port; and
a sensing element having a bottom side and a top side, the bottom side in contact with a process fluid flowing through the flow path, the flow path having a restriction height and a restriction width at a restriction plane intersecting the sensing element;
wherein a restriction ratio between the restriction height and the restriction width is 0.25 or less.

61. (canceled)

62. (canceled)

63. The fluid flow component of claim 60 further comprising a restriction element, the restriction plane intersecting the restriction element.

64. The fluid flow component of claim 60 further comprising a restriction element, the restriction height measured between the bottom side of the sensing element and the restriction element.

65.-117. (canceled)
